(19) United States
(12) Patent Application Publication
(10) Pub. No.: US 2025/0120208 A1
(43) Pub. Date: Apr. 10, 2025

(54) HYPERSPECTRAL IMAGE SENSOR INCLUDING PLANAR NANO-OPTICAL MICROLENS ARRAY AND ELECTRONIC APPARATUS INCLUDING THE IMAGE SENSOR

(71) Applicant: SAMSUNG ELECTRONICS CO., LTD., Suwon-si (KR)

(72) Inventors: Sangeun MUN, Suwon-si (KR); Suyeon LEE, Suwon-si (KR); Hyochul KIM, Suwon-si (KR); Sookyoung ROH, Suwon-si (KR)

(73) Assignee: SAMSUNG ELECTRONICS CO., LTD., Suwon-si (KR)

(21) Appl. No.: 18/906,778

(22) Filed: Oct. 4, 2024

(30) Foreign Application Priority Data
Oct. 5, 2023 (KR) 10-2023-0132508

(51) Int. Cl. H01L 27/146; B82Y 20/00

(52) U.S. Cl. CPC H10F 39/8063; B82Y 20/00; H10F 39/8053; H10F 39/8067

(57) ABSTRACT

A hyperspectral image sensor includes a planar nano-optical microlens array and an electronic apparatus including the hyperspectral image sensor are provided. The hyperspectral image sensor includes the planar nano-optical microlens array includes a plurality of planar nano-optical microlenses, each of the plurality of planar nano-optical microlenses includes a plurality of high refractive index nanostructures and a low refractive index structure, and the plurality of high refractive index nanostructures may be disposed such that light transmitted through each of the plurality of planar nano-optical microlenses has a convex phase profile.

### CROSS-REFERENCE TO RELATED APPLICATION

This application is based on and claims priority under 35 U.S.C. § 119 to Korean Patent Application No. 10-2023-0132508, filed on Oct. 5, 2023, in the Korean Intellectual Property Office, the disclosure of which is incorporated by reference herein in its entirety.

### BACKGROUND

### 1. Field

The disclosure relates to a hyperspectral image sensor including a planar nano-optical microlens array capable of easily determining an optical curvature profile of a lens surface by using a planar nanostructure, and an electronic apparatus including the hyperspectral image sensor.

### 2. Description of Related Art

As image sensors and imaging modules become smaller, a chief ray angle (CRA) at the edge of an image sensor tends to increase. As the CRA increases at the edge of the image sensor, the sensitivity of pixels positioned at the edge of the image sensor decreases. This may cause the edge of the image to be dark. In addition, additionally complex color calculations to compensate for this phenomenon put a burden on a processor that processes an image and slow down an image processing speed.

### SUMMARY

Provided are a hyperspectral image sensor including a planar nano-optical microlens array capable of easily determining an optical curvature profile of a lens surface by using a planar nanostructure, and an electronic apparatus including the hyperspectral image sensor.

Further, provided are a hyperspectral image sensor including a planar nano-optical microlens array capable of changing an angle of incidence of incident light incident at a large chief ray angle (CRA) at an edge of the hyperspectral image sensor to be nearly perpendicular, and an electronic apparatus including the hyperspectral image sensor.

Additional aspects will be set forth in part in the description which follows and, in part, will be apparent from the description, or may be learned by practice of the presented embodiments of the disclosure.

According to an aspect of an example embodiment, a hyperspectral image sensor includes: a sensor substrate including a plurality of photosensitive cells configured to detect light; a hyperspectral filter array on the sensor substrate and including a plurality of unit filters respectively corresponding to the plurality of photosensitive cells, the hyperspectral filter array being configured to separate at least four different wavelengths of the light; a buffer layer on the hyperspectral filter array; and a planar nano-optical microlens array on the buffer layer and having a nano-pattern structure configured to condense the light onto the plurality of photosensitive cells, the planar nano-optical microlens array including a plurality of planar nano-optical microlenses respectively corresponding to the plurality of unit filters, wherein each of the plurality of planar nano-optical microlenses may include first refractive index nanostructures including a first dielectric material with a first refractive index, and a second refractive index structure including a second dielectric material with a second refractive index that is lower than the first refractive index, and the first refractive index nanostructures are arranged such that the light transmitted through each of the plurality of planar nano-optical microlenses has a convex phase profile, and at a periphery of the planar nano-optical microlens array, a phase profile of the light transmitted through each of the plurality of planar nano-optical microlenses is asymmetrical with respect to a peak area of the phase profile of each of the plurality of planar nano-optical microlenses, and widths of the first refractive index nanostructures disposed in the peak area of the phase profile of each of the plurality of planar nano-optical microlenses among the plurality of first refractive index nanostructures are different from each other and are arranged differently according to center wavelengths of transmission bands of different ones of the plurality of unit filters of each of the plurality of planar nano-optical microlenses.

Smaller ones of the widths of the first refractive index nanostructures disposed in the peak area of the phase profile of each of the plurality of planar nano-optical microlenses may be arranged as overlapping larger ones of the center wavelengths of the transmission bands of the plurality of unit filters.

An effective refractive index of each of the plurality of planar nano-optical microlenses, which is determined by a ratio of each of first refractive index nanostructures to the second refractive index structure, may be greatest in a refractive index peak area of each of the plurality of planar nano-optical microlenses and is decreased towards a periphery of the refractive index peak area, the peak area of the phase profile is at the refractive index peak area, and smaller ones, of the widths of a first refractive index nanostructure having a greatest width among the first refractive index nanostructures in each of the plurality of planar nano-optical microlenses, may be arranged as overlapping larger ones of the center wavelengths of the transmission bands of the plurality of unit filters.

At a periphery of the planar nano-optical microlens array, the peak area of the phase profile of each of the plurality of planar nano-optical microlenses may be arranged from off-center of the plurality of planar nano-optical microlenses and toward a center of the planar nano-optical microlens array.

At a periphery of the planar nano-optical microlens array, a distance between the peak area of the phase profile and a center of the plurality of planar nano-optical microlenses is greater at one of the planar nano-optical microlenses further from the center of the planar nano-optic microlens array than is another one of the planar nano-optical microlenses.

At a center of the planar nano-optical microlens array, the peak area of the phase profile is positioned at a center of the plurality of planar nano-optical microlenses, and the phase profile of the light transmitted through each of the plurality of planar nano-optical microlenses may be symmetrical with respect to the center of the plurality of planar nano-optical microlenses.

Each of the plurality of unit filters may include: a first reflector; a second reflector on an upper portion of the first reflector; and a plurality of cavities between the first reflector and the second reflector, and having resonance wavelengths of different bands.

The plurality of cavities may have the resonance wavelengths of different bands by having different thicknesses and different effective refractive indices than each other.

Thicknesses of portions of the buffer layer on upper portions of each of the plurality of cavities may be different than each other according to the thicknesses of the plurality of cavities.

A combined thickness of the plurality of cavities and the portions of the buffer layer may be constant.

each of the plurality of cavities may have a same thickness, and each of the plurality of cavities may include a first dielectric and a second dielectric which include different refractive indices than each other.

Each of the first refractive index nanostructures may have a nano-post shape, and in each of the plurality of planar nano-optical microlenses, the second refractive index structure may surround the first refractive index nanostructures.

Each of the first refractive index nanostructures may have a nano-post shape, and in each of the plurality of planar nano-optical microlenses, the first refractive index nanostructures may be arranged in any one of a 3×3 arrangement, a 4×4 arrangement, and a 5×5 arrangement.

Each of the plurality of planar nano-optical microlenses may include a first layer and a second layer on the first layer.

Each of the plurality of planar nano-optical microlenses may include a first layer and a second layer on the first layer, and at a periphery of the planar nano-optical microlens array, a distribution of ones of the first refractive index nanostructures and the second refractive index structure at the first layer may be different from a distribution of other ones of the first refractive index nanostructures and the second refractive index structure at the second layer.

A thickness of the buffer layer may be 1 to 3 times a longest wavelength of the light as transmitted by the plurality of unit filters.

The hyperspectral image sensor may further include an anti-reflection film on the planar nano-optical microlens array.

The hyperspectral image sensor may further include a plurality of band blocking filters configured to transmit only a specific wavelength band of the light and to absorb or reflect other wavelength bands of the light between the planar nano-optical microlens array and the hyperspectral filter array.

According to an aspect of an example embodiment, an electronic apparatus includes: a hyperspectral image sensor configured to convert an optical image into an electrical signal; and a processor configured to control an operation of the hyperspectral image sensor and store and output a signal generated by the hyperspectral image sensor, wherein the hyperspectral image sensor may include: a sensor substrate including a plurality of photosensitive cells configured to detect light; a hyperspectral filter array on the sensor substrate and including a plurality of unit filters respectively corresponding to the plurality of photosensitive cells, the hyperspectral filter array being configured to separate at least four different wavelengths of the light; a buffer layer on the hyperspectral filter array; and a planar nano-optical microlens array on the buffer layer and having a nano-pattern structure configured to condense the light onto the plurality of photosensitive cells, the planar nano-optical microlens array including a plurality of planar nano-optical microlenses respectively corresponding to the plurality of unit filters, wherein each of the plurality of planar nano-optical microlenses may include first refractive index nanostructures including a first dielectric material with a first refractive index, and a second refractive index structure including a second dielectric material with a second refractive index that is lower than the first refractive index, and the first refractive index nanostructures are arranged such that the light, as transmitted through each of the plurality of planar nano-optical microlenses has a convex phase profile, and at a periphery of the planar nano-optical microlens array, a phase profile of the light transmitted through each of the plurality of planar nano-optical microlenses, is asymmetrical with respect to a peak area of the phase profile of each of the plurality of planar nano-optical microlenses, and widths of the first refractive index nanostructures disposed in the peak area of the phase profile of each of the plurality of planar nano-optical microlenses among the plurality of first refractive index nanostructures are different from each other and are arranged differently according to center wavelengths of a transmission bands of different ones of the plurality of unit filters each of the plurality of planar nano-optical microlenses.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic block diagram of a hyperspectral image sensor according to one or more embodiments;

FIG. 2 is a conceptual diagram schematically showing a camera module according to one or more embodiments;

FIG. 3 is a cross-sectional view showing a pixel array of a hyperspectral image sensor according to one or more embodiments;

FIG. 4A is a schematic cross-sectional view of the center of the pixel array of the hyperspectral image sensor shown in FIG. 3;

FIG. 4B shows convex microlenses respectively equivalent to planar nano-optical microlenses shown in FIG. 4A;

FIG. 5A is a plan view showing a shape of the planar nano-optical microlens shown in FIG. 4A;

FIG. 5B shows a phase profile of light immediately after transmitting through the planar nano-optical microlens;

FIG. 6 is a plan view showing an effective refractive index distribution of the planar nano-optical microlenses shown in FIG. 4A;

FIG. 7A is a schematic cross-sectional view of a periphery of the pixel array of the hyperspectral image sensor shown in FIG. 3;

FIG. 7B is a plan view illustrating a shape of the planar nano-optical microlens shown in FIG. 7A;

FIG. 8A is a plan view showing an effective refractive index distribution of the planar nano-optical microlens shown in FIG. 7A;

FIG. 8B is a plan view showing a shape of the planar nano-optical microlens shown in FIG. 7A;

FIG. 8C is a plan view showing a shape of the planar nano-optical microlens shown in FIG. 7A;

FIG. 9 is an exemplary cross-sectional view showing an effective refractive index distribution of the planar nano-optical microlens shown in FIG. 7A;

FIG. 10 is a plan view schematically showing a plurality of zones of the nano-optical microlens array according to one or more embodiments;

FIG. 11 is a plan view schematically showing an arrangement of a plurality of unit filters in a hyperspectral filter array according to one or more embodiments;

FIG. 12A is a cross-sectional view showing a distribution of nanostructures of a planar nano-optical microlens array provided on the plurality of unit filters of the hyperspectral filter array of FIG. 11;

FIG. 12B is a cross-sectional view showing a distribution of nanostructures of a planar nano-optical microlens array provided on the plurality of unit filters of the hyperspectral filter array of FIG. 11;

FIG. 13 is a plan view schematically showing of a plurality of unit filters of a hyperspectral filter array according to one or more embodiments;

FIG. 14A is a cross-sectional view showing a distribution of nanostructures of a planar nano-optical microlens array provided on the plurality of unit filters of the hyperspectral filter array of FIG. 13;

FIG. 14B is a cross-sectional view showing a distribution of nanostructures of a planar nano-optical microlens array provided on the plurality of unit filters of the hyperspectral filter array of FIG. 13;

FIG. 15 is a plan view showing another example of the shape of the planar nano-optical microlens shown in FIG. 5A;

FIG. 16 is a plan view showing another example of the shape of the planar nano-optical microlens shown in FIG. 5A;

FIG. 17A is a cross-sectional view illustrating the pixel array of the hyperspectral image sensor shown in FIG. 4A according to one or more embodiments;

FIG. 17B is a cross-sectional view illustrating the pixel array of the hyperspectral image sensor shown in FIG. 4A according to one or more embodiments;

FIG. 17C is a cross-sectional view illustrating the pixel array of the hyperspectral image sensor shown in FIG. 4A according to one or more embodiments;

FIG. 17D is a cross-sectional view illustrating the pixel array of the hyperspectral image sensor shown in FIG. 4A according to one or more embodiments;

FIG. 17E is a cross-sectional view illustrating the pixel array of the hyperspectral image sensor shown in FIG. 4A according to one or more embodiments;

FIG. 18A is a cross-sectional view showing a shape of planar nano-optical microlenses according to one or more embodiments;

FIG. 18B is a cross-sectional view showing a shape of planar nano-optical microlenses according to one or more embodiments;

FIG. 19 is a block diagram illustrating an example of an electronic apparatus including an image sensor;

FIG. 20 is a block diagram schematically illustrating a camera module of FIG. 19;

FIG. 21 is a block diagram of an electronic device including a multi-camera module; and

FIG. 22 is a detailed block diagram of one camera module of the electronic device shown in FIG. 21.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a hyperspectral image sensor including a planar nano-optical microlens array, and electronic apparatus including the hyperspectral image sensor will be described in detail with reference to the accompanying drawings. The embodiments of the disclosure may be variously modified and may be embodied in many different forms. In the following drawings, like reference numerals refer to like components, and the size of each component in the drawings may be exaggerated for clarity and convenience of description.

Hereinafter, what is described as “upper” or “on” may include those directly above, below, left, and right in contact, as well as above, below, left, and right in non-contact.

The terms such as “first” or “second” used herein may be used to describe various components, but may be used for the purpose of distinguishing one component from another component. These terms do not limit the difference in the material or structure of the components.

The singular forms are intended to include the plural forms as well, unless the context clearly indicates otherwise. When a part “comprises” or “includes” a component in the specification, unless otherwise defined, it is not excluding other components but may further include other components.

Also, in the specification, the term “unit” or “module” denote a unit or a module that processes at least one function or operation, and may be implemented by hardware, software, or a combination of hardware and software.

The term “above” and similar directional terms may be applied to both singular and plural.

Operations of a method described herein may be performed in any suitable order unless explicitly stated that they must be performed in the order described. In addition, the use of all exemplary terms (e.g., etc.) is merely for describing the technical idea in detail, and unless limited by the claims, the scope of rights is not limited by these terms.

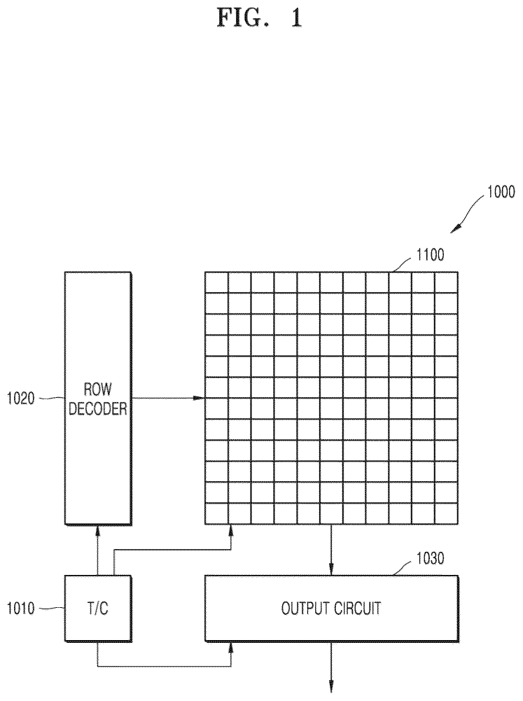

FIG. 1 is a schematic block diagram of a hyperspectral image sensor 1000 according to one or more embodiments. Referring to FIG. 1, the hyperspectral image sensor 1000 may include a pixel array 1100, a timing controller 1010 (“T/C”), a row decoder 1020, and an output circuit 1030.

The pixel array 1100 includes pixels that are two-dimensionally arranged along a plurality of rows and columns. The row decoder 1020 selects one of the rows of the pixel array 1100 in response to a row address signal output from the timing controller 1010. The output circuit 1030 outputs a photosensitive signal, in a column unit, from a plurality of pixels arranged along the selected row. To this end, the output circuit 1030 may include a column decoder and an analog-to-digital converter (ADC). For example, the output circuit 1030 may include the column decoder and a plurality of ADCs respectively disposed for each column between the column decoder and the pixel array 1100, or one ADC disposed at an output terminal of the column decoder. The timing controller 1010, the row decoder 1020, and the output circuit 1030 may be implemented as one chip or as separate chips. A processor processing an image signal output through the output circuit 1030 may be implemented as a single chip together with the timing controller 1010, the row decoder 1020, and the output circuit 1030.

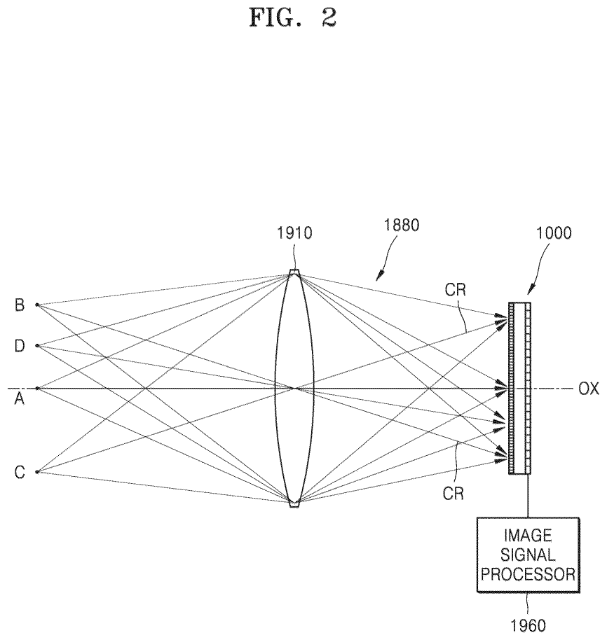

The hyperspectral image sensor 1000 may be applied to various optical apparatus such as a camera module. For example, FIG. 2 is a conceptual diagram schematically showing a camera module 1880 according to one or more embodiments.

Referring to FIG. 2, the camera module 1880 according to one or more embodiments may include a lens assembly 1910 that forms an optical image by focusing light reflected from an object, the hyperspectral image sensor 1000 that converts the optical image formed by the lens assembly 1910 into an electrical image signal, and an image signal processor 1960 that processes the electrical signal output from the hyperspectral image sensor 1000 into an image signal. The camera module 1880 may also include a display panel that displays an image generated by the image signal processor 1960 and a memory that stores image data generated by the image signal processor 1960. The camera module 1880 may be mounted on, for example, a mobile electronic apparatus such as a cell phone, laptop, tablet PC, etc.

The lens assembly 1910 serves to focus an image of a subject outside the camera module 1880 onto the hyperspectral image sensor 1000, more precisely, onto the pixel array 1100 of the hyperspectral image sensor 1000. In FIG. 2, a single lens is briefly shown for convenience, but the actual lens assembly 1910 may include a plurality of lenses. When the pixel array 1100 is accurately positioned on a focal plane of the lens assembly 1910, light starting from a point on the subject is again collected to a point on the pixel array 1100 through the lens assembly 1910. For example, light starting from a point A on an optical axis OX passes through the lens assembly 1910 and then is collected at the center of the pixel array 1100 on the optical axis OX. Light starting from a point B, point C, or point D off the optical axis OX crosses the optical axis OX by the lens assembly 1910 and is collected at a point on the periphery of the pixel array 1100. For example, in FIG. 2, light starting from the point B above the optical axis OX is collected at a lower edge of the pixel array 1100 across the optical axis OX, and light starting from the point C below the optical axis OX crosses the optical axis OX and is collected at an upper edge of the pixel array 1100. In addition, light starting from the point D positioned between the optical axis OX and the point B is collected between the center and lower edge of the pixel array 1100.

Therefore, the light starting from different ones of point A, point B, pont C, and point D is incident on the pixel array 1100 at different angles according to distances between the point A, the point B, the point C, and the point D and the optical axis OX. An angle of incidence of light incident on the pixel array 1100 is typically defined as a chief ray angle (CRA). The chief ray refers to a ray that passes through the center of the lens assembly 1910 from one point of the subject and is incident on the pixel array 1100, and the CRA refers to the angle that the chief ray makes with the optical axis OX. Light starting from the point A on the optical axis OX has a CRA of 0 degree and is incident perpendicularly on the pixel array 1100. As a start point moves away from the optical axis OX, the CRA increases.

From the perspective of the hyperspectral image sensor 1000, the CRA of light incident on the center of the pixel array 1100 is 0 degree, and the CRA of incident light increases toward the edge of the pixel array 1100. For example, the CRA of light starting from the point B and the point C and incident on the edge of the pixel array 1100 is the greatest, and the CRA of light starting from the point A and incident on the center of the pixel array 1100 is 0 degree. In addition, the CRA of light starting from the point D and incident between the center and edge of the pixel array 1100 is smaller than the CRA of light starting from the point B and the point C and is greater than 0 degree.

Accordingly, the CRA of the incident light incident on pixels varies depending on positions of the pixels within the pixel array 1100. In particular, the CRA gradually increases from the center of the pixel array 1100 to the edge of the pixel array 1100. When the CRA of the incident light incident on the pixels increases, sensitivity of the pixels may decrease. According to one or more embodiments, in order to prevent or minimize a decrease in the sensitivity of the pixels positioned at the edge of the pixel array 1100, a planar nano-optical microlens array may be provided in the pixel array 1100 of the hyperspectral image sensor 1000.

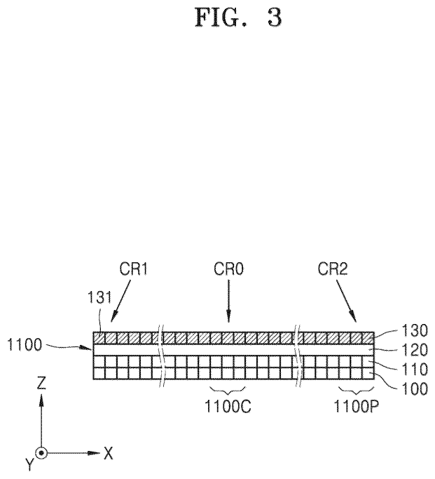

FIG. 3 is a cross-sectional view showing the pixel array 1100 of the hyperspectral image sensor 1000 according to one or more embodiments. Referring to FIG. 3, the pixel array 1100 of the hyperspectral image sensor 1000 may include a sensor substrate 100, a hyperspectral filter array 110 disposed on the sensor substrate 100, a buffer layer 120 disposed on the hyperspectral filter array 110, and a planar nano-optical microlens array 130 disposed on the buffer layer 120. The planar nano-optical microlens array 130 may include a plurality of planar nano-optical microlenses (e.g., planar nano-optical microlens 131, planar nano-optical microlens 132, planar nano-optical microlens 133, and planar nano-optical microlens 134). As shown in FIG. 3, a CRA CR0 may be incident on a center 1100C of the pixel array 1100 at a perpendicular or nearly perpendicular angle, whereas CRAs CR1 and CR2 may be obliquely incident on a periphery 1100P of the pixel array 1100. Accordingly, the plurality of planar nano-optical microlenses (e.g., planar nano-optical microlens 131, planar nano-optical microlens 132, planar nano-optical microlens 133, and planar nano-optical microlens 134) disposed at the center 1100C of the pixel array 1100 and the plurality of planar nano-optical microlenses (e.g., planar nano-optical microlens 131, planar nano-optical microlens 132, planar nano-optical microlens 133, and planar nano-optical microlens 134) disposed at the periphery 1100P of the pixel array 1100 may be differently designed considering angles of incidence of the CRAs CR0, CR1, and CR2.

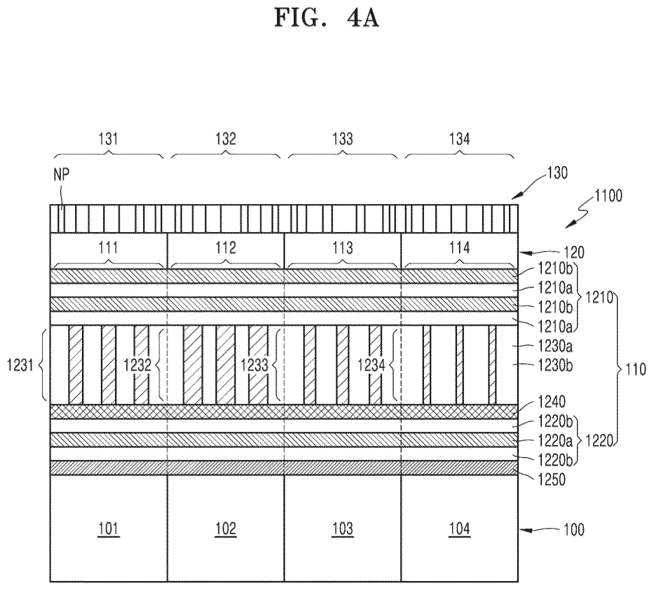

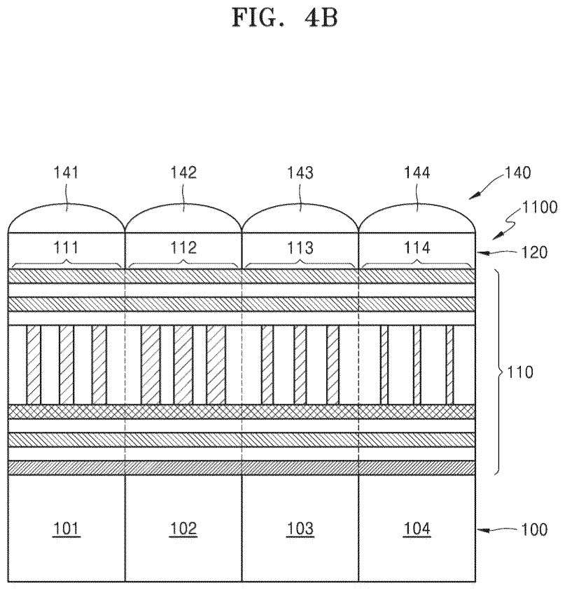

FIG. 4A is a schematic cross-sectional view of the center 1100C of the pixel array 1100 of the hyperspectral image sensor 1000 shown in FIG. 3. Referring to FIG. 3, FIG. 4A, and FIG. 4B, the sensor substrate 100 may include a plurality of photosensitive cells that sense light. For example, the sensor substrate 100 may include a plurality of first photosensitive cells 101, a plurality of second photosensitive cells 102, a plurality of third photosensitive cells 103, and a plurality of fourth photosensitive cells 104. For convenience, FIG. 4A shows that the first photosensitive cell 101, the second photosensitive cell 102, the third photosensitive cell 103, and the fourth photosensitive cell 104are sequentially arranged in a first direction (X direction), but the disclosure is not necessarily limited thereto. The first photosensitive cell 101, the second photosensitive cell 102, the third photosensitive cell 103, and the fourth photosensitive cell 104of the sensor substrate 100 may be two-dimensionally arranged in various ways.

The hyperspectral filter array 110 may include a plurality of unit filters, each corresponding to the first photosensitive cell 101, the second photosensitive cell 102, the third photosensitive cell 103, and the fourth photosensitive cell 104. The hyperspectral filter array 110 may separate light of at least four different wavelengths. For example, the hyperspectral filter array 110 may separate light of sixteen different wavelengths. Alternatively, the hyperspectral filter array 110 may separate light of four different wavelengths. The hyperspectral filter array 110 may include a plurality of unit filters that transmit only light in a specific wavelength band and absorb or reflect light in wavelength bands other than the specific wavelength band. For example, the hyperspectral filter array 110 may include a first unit filter 111 disposed on the first photosensitive cell 101 and transmitting only light in a first wavelength band, a second unit filter 112 disposed on the second photosensitive cell 102 and transmitting only light in a second wavelength band different from the first wavelength band, a third unit filter 113 disposed on the third photosensitive cell 103 and transmitting only light in a third wavelength band different from the first and second wavelength bands, and a fourth unit filter 114 disposed on the fourth photosensitive cell 104 and transmitting only light in a fourth wavelength band different from the first to third wavelength bands. For convenience, FIG. 4A shows that the first unit filter 111, the second unit filter 112, the third unit filter 113, and the fourth unit filter 114 are sequentially arranged in the first direction (X direction), but the disclosure is not necessarily limited thereto. The first unit filter 111, the second unit filter 112, the third unit filter 113, and the fourth unit filter 114 of the hyperspectral filter array 110 may be two-dimensionally arranged in various ways.

The first unit filter 111, the second unit filter 112, the third unit filter 113, and the fourth unit filter 114 of the hyperspectral filter array 110 may each include first reflector 1210 and second reflector 1220 that are spaced apart from each other, and may respectively include a plurality of cavities (e.g., cavity 1231, cavity 1232, cavity 1233, and cavity 1234_provided between the first reflector 1210 and the second reflector 1220.

The first reflector 1210 and the second reflector 1220.may each include a Bragg reflector. The Bragg reflector may be a Distributed Bragg Reflector (DBR) having a structure in which two or more dielectrics with different refractive indices are alternately stacked. FIG. 4A shows that the first reflector 1210 includes a Bragg reflector in which two dielectrics, dielectric 1210a and dielectric 1210b, are alternately stacked, and the second reflector 1220 includes a Bragg reflector in which the dielectric 2210a and the dielectric 2210b are alternately stacked.

The first reflectors 1210 and the second reflector 1220 may each include a metal reflector. The metal reflector may include, for example, Al, Ag, Au, Cu, Ti, W, or TiN, but is not limited thereto. In addition, the first reflector 1210 and the second reflector 1220 may include different material films. For example, the first reflector 1210 may include a metal reflector, and the second reflector 1220 may include a Bragg reflector. However, this is merely an example.

The first cavity 1231, the second cavity 1232, the third cavity 1233, and the fourth cavity 1234 are provided between the first reflector 1210 and the second reflector 1220. The first cavity 1231, the second cavity 1232, the third cavity 1233, and the fourth cavity 1234 may have different resonance wavelengths. The first cavity 1231, the second cavity 1232, the third cavity 1233, and the fourth cavity 1234 may be configured to have different resonance wavelengths by adjusting their respective thicknesses and effective refractive indices.

A passivation layer 1250 may be provided between the second reflector 1220 and the sensor substrate 100 to protect the first photosensitive cell 101, the second photosensitive cell 102, the third photosensitive cell 103, and the fourth photosensitive cell 104. The passivation layer 1250 may include, for example, hafnium oxide, silicon oxide, or silicon nitride, but is not limited thereto.

An etch stop layer 1240 may be further provided between the second reflector 1220 and the first cavity 1231, the second cavity 1232, the third cavity 1233, and the fourth cavity 1234. The etch stop layer 1240 may serve to facilitate a patterning process for forming the first cavity 1231, the second cavity 1232, the third cavity 1233, and the fourth cavity 1234. The etch stop layer 1240 may include, for example, titanium oxide or hafnium oxide, but is not limited thereto. For example, the etch stop layer 1240 may include a material of which etch rate is at least two times (e.g., at least five times) slower than a dielectric material constituting the first cavity 1231, the second cavity 1232, the third cavity 1233, and the fourth cavity 1234, but is not limited thereto.

A buffer layer 120 may be provided on the hyperspectral filter array 110. The buffer layer 120 may serve as a spacer to secure a focal length of the planar nano-optical microlens array 130, which will be described below. In addition, the buffer layer 120 may prevent a mutual interference between the planar nano-optical microlens array 130 and the hyperspectral filter array 110 disposed with the buffer layer 120 therebetween. In addition, the buffer layer 120 may provide a sufficient travel distance of light for the planar nano-optical microlens array 130, which will be described below, to modulate a phase profile. To this end, a thickness of the buffer layer 120 may be sufficiently thick. For example, the thickness of the buffer layer 120 may be 1 to 3 times the longest wavelength among wavelengths transmitted by the first unit filter 111, the second unit filter 112, the third unit filter 113, and the fourth unit filter 114.

The planar nano-optical microlens array 130 may be provided on the buffer layer 120. The planar nano-optical microlens array 130 may include a plurality of the planar nano-optical microlens 131, the planar nano-optical microlens 132, the planar nano-optical microlens 133, and the planar nano-optical microlens 134 two-dimensionally arranged. The plurality of the planar nano-optical microlens 131, the planar nano-optical microlens 132, the planar nano-optical microlens 133, and the planar nano-optical microlens 134 may correspond one-to-one the plurality of the first unit filter 111, the second unit filter 112, the third unit filter 113, and the fourth unit filter 114, and also may correspond one-to-one the plurality of the first photosensitive cell 101, the second photosensitive cell 102, the third photosensitive cell 103, and the fourth photosensitive cell 104. Each of the plurality of the planar nano-optical microlens 131, the planar nano-optical microlens 132, the planar nano-optical microlens 133, and the planar nano-optical microlens 134 may be configured to condense light on a corresponding photosensitive cell among the plurality of the first photosensitive cell 101, the second photosensitive cell 102, the third photosensitive cell 103, and the fourth photosensitive cell 104. To this end, the plurality of the planar nano-optical microlens 131, the planar nano-optical microlens 132, the planar nano-optical microlens 133, and the planar nano-optical microlens 134 may each have a nano-pattern structure capable of condensing light. The nano-pattern structure may include a plurality of high refractive index nanostructures (e.g., in the form of nano-posts (NPs)) and low refractive index structures that change a phase of incident light differently according to a position of incidence. The high refractive index nanostructure with a difference in refractive index from a peripheral material may change a phase of light that transmitted therethrough. This is due to a phase delay caused by the shape dimension of a sub-wavelength of the high refractive index nanostructure, and a degree of phase delay is determined by a detailed shape dimension and an arrangement form of the high refractive index nanostructure. The shape, size (width and height), space, arrangement form, etc. of the plurality of high refractive index nanostructures may be determined such that light immediately after transmitting through each of the planar nano-optical microlens 131, the planar nano-optical microlens 132, the planar nano-optical microlens 133, and the planar nano-optical microlens 134 has a certain phase profile. According to the phase profile, a travel direction and focal distance of light transmitting through each of the planar nano-optical microlens 131, the planar nano-optical microlens 132, the planar nano-optical microlens 133, and the planar nano-optical microlens 134 may be determined. Hereinafter, for convenience of explanation, the planar nano-optical microlens 131 is described as an example, but the description below may be similarly applied to the other of the planar nano-optical microlens 132, the planar nano-optical microlens 133, and the planar nano-optical microlens 134.

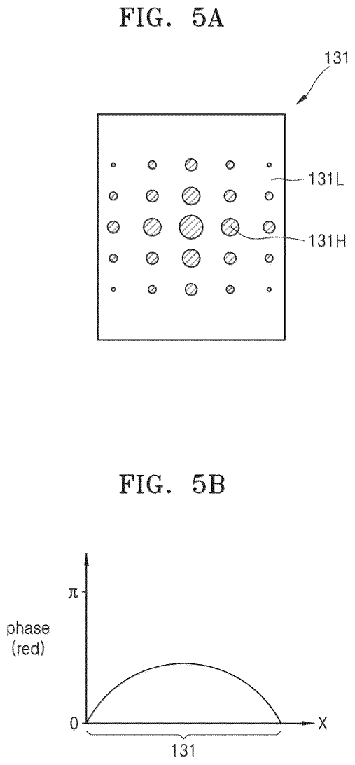

FIG. 5A is a plan view showing a shape of the planar nano-optical microlens 131 shown in FIG. 4A, and FIG. 5B shows a phase profile of light immediately after transmitting through the planar nano-optical microlens 131.

Referring to FIG. 5A, the planar nano-optical microlens 131 may include high refractive index nanostructures 131H and a low refractive index structure 131L filled between the high refractive index nanostructures 131H. For example, the planar nano-optical microlens 131, the planar nano-optical microlens 132, the planar nano-optical microlens 133, and the planar nano-optical microlens 134 may include a plurality of high refractive index structures 131H having a cylindrical shape and the low refractive index structure 131L surrounding the plurality of high refractive index structures 131H described above. FIG. 5A shows that the high refractive index nanostructure 131H is provided in a 5×5 arrangement, but the disclosure is not limited thereto. The high refractive index nanostructures 131H may include a dielectric material with a relatively high refractive index but a low absorption in a visible light band, such as TiO₂, GaN, SiN₃, ZnS, ZnSe, Si₃N₄, etc., and the low refractive index structure 131L may include a dielectric material with a relatively low refractive index but a low absorption in a visible light band, such as SiO₂, silanol-based glass (SOG), air, etc. For example, the refractive index of the high refractive index nanostructure 131H may be about 2.0 or more with respect to light with a wavelength of about 630 nm, and the refractive index of the low refractive index structure 131L may be about 1.0 or more and less than 2.0 with respect to light with a wavelength of about 630 nm. In addition, a difference between the refractive index of the high refractive index nanostructure 131H and the refractive index of the low refractive index structure 131L may be about 0.5 or more.

In order for the planar nano-optical microlens 131 to function as a convex lens that converges light, an effective refractive index of the planar nano-optical microlens 131 may be greatest in one area of the planar nano-optical microlens 131 and may gradually decrease towards the periphery of the area. Here, the effective refractive index may correspond to a ratio of the high refractive index nanostructure 131H to the low refractive index structure 131L within each planar nano-optical microlens 131. In other words, the ratio of the high refractive index nanostructure 131H to the low refractive index structure 131L may be greatest in one area of the planar nano-optical microlens 131 and gradually decrease toward the periphery of the area. Hereinafter, the area with the greatest effective refractive index within the planar nano-optical microlens 131 is referred to as a “refractive index peak area.” To satisfy these conditions, a width or pitch of each of the low-refractive-index structure 131L and the high-refractive-index nanostructure 131H may be selected differently from the refractive index peak area of the planar nano-optical microlens 131 and the periphery thereof. For example, the width or diameter of each of the plurality of high refractive index nanostructures 131H may be greatest at the refractive index peak area and gradually decrease toward the periphery. In other words, the high refractive index nanostructure 131H with the greatest width or diameter in the planar nano-optical microlens 131 disposed at the center 1100C of the pixel array 1100 may be disposed in the innermost of the planar nano-optical microlens 131. The width or diameter of the high refractive index nanostructure 131H may gradually decrease further away from the center of the planar nano-optical microlens 131.

In addition, the planar nano-optical microlens 131 may serve to change an angle of incidence of incident light such that light is incident almost nearly perpendicular on the center of a photosensitive cell corresponding thereto. As described above, a CRA of incident light varies depending on a position on the pixel array 1100. Accordingly, a position of the refractive index peak area within the planar nano-optical microlens 131 may vary depending on a position of the planar nano-optical microlens 131 within the pixel array 1100.

Referring to FIG. 5B, a phase of the light immediately after transmitting through the planar nano-optical microlens 131 may be greatest the center of the nano-optical microlens 131, and may decrease further away from the center of the planar nano-optical microlens 131 in the first direction (X direction).

In the center 1100C of the pixel array 1100 where the CRA is 0 degree in both the first direction (X direction) and a second direction (Y direction), the planar nano-optical microlens 131 does not need to change the travel direction of incident light, and thus, the planar nano-optical microlens 131 may be configured to implement a convex curved phase profile that is symmetrical in both the first direction (X direction) and the second direction (Y direction). Referring again to FIG. 5A, in order to implement the phase profile above, a plurality of high refractive index nanostructures may be arranged symmetrically in the first direction (X direction) and the second direction (Y direction) in the planar nano-optical microlens 131 with respect to the center of the planar nano-optical microlens 131. In particular, the high refractive index nanostructures arranged in the center of the planar nano-optical microlens 131 may have the greatest diameter so that the greatest phase delay occurs in the center of the planar nano-optical microlens 131, and the diameter of the high refractive index nanostructure may gradually decrease further away from the center of each optical microlens 131. For example, the high refractive index nanostructures respectively disposed at four vertices of the planar nano-optical microlens 131 may have the smallest diameter.

However, the diameter of the high refractive index nanostructure disposed in an area where the phase delay is relatively small is not necessarily relatively small. The phase profile illustrated in FIG. 5B is expressed as the remainder after subtracting 2 nπ (n is an integer greater than 0) from an actual phase delay. For example, when a phase delay in an area is 3 π, the phase delay is optically equal to the π remaining after removing 2 π. Therefore, when it is difficult to manufacture the high refractive index nanostructure because its diameter is small, the diameter of the high refractive index nanostructure may be selected to implement a phase delay increased by 2 π. For example, when the diameter of the high refractive index nanostructure to achieve a phase delay of 0.1 π is too small, the diameter of the high refractive index nanostructure may be selected to achieve a phase delay of 2.1 π. Therefore, in this case, the diameters of the high refractive index nanostructures arranged at the four vertex areas of the planar nano-optical microlens 131 may be the greatest.

Considering the above explanation, a peak area of the phase profile may be an area with a nanostructure having the greatest width, but may also be an area with a nanostructure having the smallest width. In other words, the peak area of the phase profile may be the area with the greatest or smallest effective refractive index. To summarize according to one or more embodiments, the peak area of the phase profile may be the same as a refractive index peak area with the greatest effective refractive index, and as another example, the peak area of the phase profile may be the same as an area with the smallest effective refractive index.

When the planar nano-optical microlens 131 is disposed in the center 1100C of the pixel array 1100 where an incident light Li is incident almost nearly perpendicular, the planar nano-optical microlens 131 does not need to change an angle at which the light travels. Therefore, as shown in FIG. 4A, the refractive index peak area of the planar nano-optical microlens 131 disposed at the center 1100C of the pixel array 1100 may be positioned at the center of the planar nano-optical microlens 131. A peak of the phase profile of the light transmitting through the planar nano-optical microlens 131 disposed at the center 1100C of the pixel array 1100 may be positioned at the center of a planar nano-optical microlens, and the phase profile of the light transmitting through the planar nano-optical microlens 131 may be symmetrical with respect to the center of the planar nano-optical microlens.

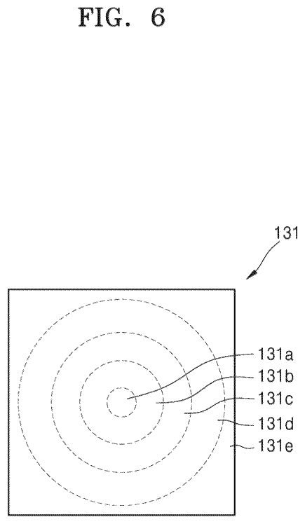

FIG. 6 is a plan view showing an effective refractive index distribution of the planar nano-optical microlens 131 shown in FIG. 4A. Referring to FIG. 6, the planar nano-optical microlens 131 disposed at the center 1100C of the pixel array 1100 may include a first area 131a disposed at the center, a second area 131b adjacent to the first area 131a and surrounding the first area 131a, a third area 131c adjacent to the second area 131b and surrounding the second area 131b, a fourth area 131d adjacent to the third area 131c and surrounding the third area 131c, and a fifth area 131e adjacent to the fourth area 131d and surrounding the fourth area 131d. The first to fifth areas 131a to 131e may be arranged in a concentric circle with the center of the planar nano-optical microlens 131 as the origin.

The first area 131a positioned in the very center is an area with the greatest effective refractive index. In other words, a ratio of the high refractive index nanostructure 131H to the low refractive index structure 131L is the greatest in the first area 131a. The planar nano-optical microlens 131 may have an effective refractive index distribution in which the effective refractive index gradually decreases from the first area 131a to the fifth area 131e. The effective refractive index of the second area 131b is lower than the effective refractive index of the first area 131a, the effective refractive index of the third area 131c is lower than the effective refractive index of the effective refractive index of the second area 131b, and the effective refractive index of the fourth area 131d is lower than the effective refractive index of the third area 131c. Also, the effective refractive index of the fifth area 131e is the lowest. To this end, at least one of the width or pitch of the low refractive index structure 131L and the high refractive index nanostructure 131H in the first area 131a to the fifth area 131e may be selected differently. FIG. 6 shows that the planar nano-optical microlens 131 includes areas with five different effective refractive indices, but the disclosure is not limited thereto. The number of areas with different effective refractive indices within one planar nano-optical microlens 131 may be selected depending on design conditions in various ways.

In this structure, the planar nano-optical microlens 131 may have a symmetrical effective refractive index distribution with respect to the center of the planar nano-optical microlens 131. In addition, the refractive index peak area of the planar nano-optical microlens 131 is positioned at the center of the planar nano-optical microlens 131, particularly the first area 131a. FIG. 6 shows that the planar nano-optical microlens 131 has five concentric circles, but the disclosure is not necessarily limited thereto. For example, the distribution and number of concentric circle areas may be differently selected according to the size of the planar nano-optical microlens 131, the effective refractive index distribution profile required for the planar nano-optical microlens 131, the phase profile of light transmitted through the planar nano-optical microlens 131, etc.

FIG. 4B shows the convex microlens 141, the convex microlens 142, the convex microlens 143, and the convex microlens 144 respectively equivalent to the planar nano-optical microlens 131, the planar nano-optical microlens 132, the planar nano-optical microlens 133, and the planar nano-optical microlens 134 shown in FIG. 4A. When the planar nano-optical microlens 131, the planar nano-optical microlens 132, the planar nano-optical microlens 133, and the planar nano-optical microlens 134 shown in FIG. 4A have the effective refractive index distribution shown in FIG. 6, the same optical effect may be obtained as that an optical axis positioned at the center of equivalent the convex microlens 141, the convex microlens 142, the convex microlens 143, and the convex microlens 144 coincides with the center of photosensitive cells and color filters corresponding to the convex microlens 141, the convex microlens 142, the convex microlens 143, and the convex microlens 144. In addition, the equivalent the convex microlens 141, the convex microlens 142, the convex microlens 143, and the convex microlens 144 may have a symmetrical lens surface with respect to the optical axis. In this case, light incident perpendicularly on the pixel array 1100 may pass through the planar nano-optical microlens 131, the planar nano-optical microlens 132, the planar nano-optical microlens 133, and the planar nano-optical microlens 134 and the hyperspectral filter array 110 and then incident perpendicularly on the sensor substrate 100. Therefore, at the center of the pixel array 1100, the refractive index peak area may be positioned at the center of the planar nano-optical microlens 131, the planar nano-optical microlens 132, the planar nano-optical microlens 133, and the planar nano-optical microlens 134, and the planar nano-optical microlens 131, the planar nano-optical microlens 132, the planar nano-optical microlens 133, and the planar nano-optical microlens 134 may be arranged so that the refractive index peak area coincides with the center of the corresponding photosensitive cells and color filters.

Meanwhile, at the edge 1100P of the pixel array 1100, incident light is obliquely incident on the pixel array 1100. The angle of incidence of incident light gradually increases from the center 1100C to the periphery 1100P of the pixel array 1100, and is the greatest at the periphery 1100P of the pixel array 1100. Therefore, the planar nano-optical microlens 131, the planar nano-optical microlens 132, the planar nano-optical microlens 133, and the planar nano-optical microlens 134 disposed at the periphery of the planar nano-optical microlens array 130 may be configured to deflect incident light toward the center of the corresponding photosensitive cells to prevent or minimize deterioration of the sensitivity of pixels. Then, the planar nano-optical microlens 131, the planar nano-optical microlens 132, the planar nano-optical microlens 133, and the planar nano-optical microlens 134 may condense the incident light on the center of the corresponding photosensitive cells regardless of the angle of incidence of the incident light. To this end, the high refractive index nanostructures 131H respectively disposed on the planar nano-optical microlens 131, the planar nano-optical microlens 132, the planar nano-optical microlens 133, and the planar nano-optical microlens 134 may be designed to deflect the travel direction of incident light. The high refractive index nanostructures 131H respectively disposed on the planar nano-optical microlens 131, the planar nano-optical microlens 132, the planar nano-optical microlens 133, and the planar nano-optical microlens 134 may be arranged so that light transmitted through each of the planar nano-optical microlens 131, the planar nano-optical microlens 132, the planar nano-optical microlens 133, and the planar nano-optical microlens 134 has a convex phase profile.

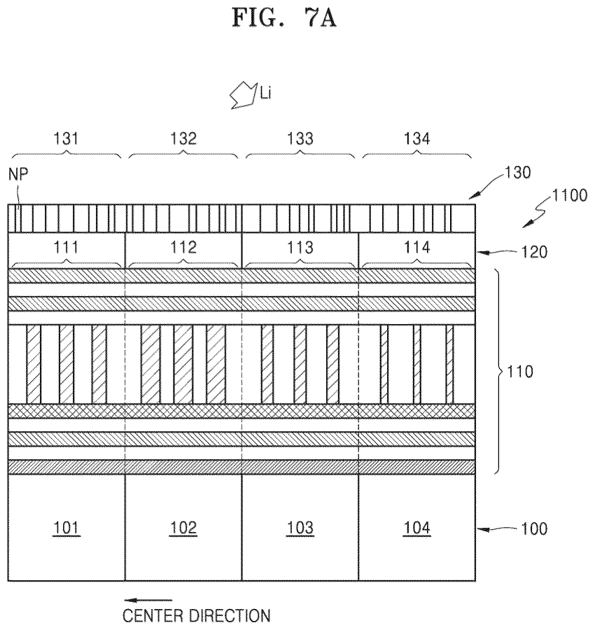

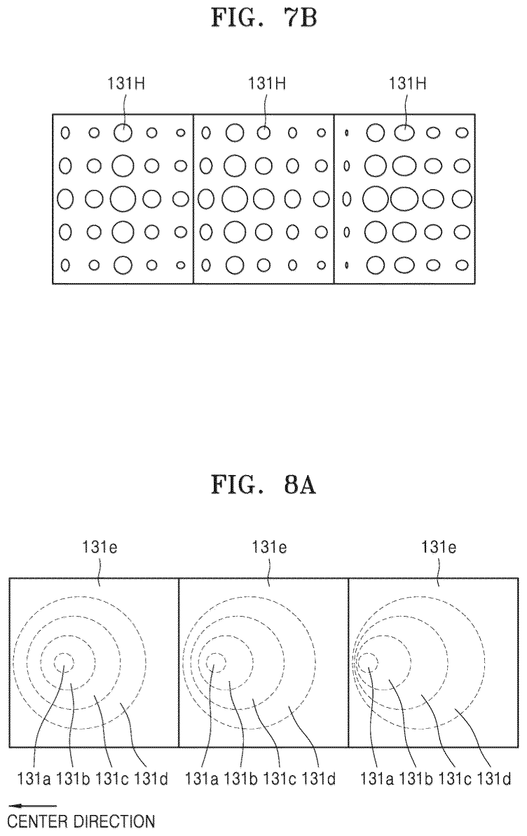

FIG. 7A is a schematic cross-sectional view of the periphery 1100P of the pixel array 1100 of the hyperspectral image sensor 1000. Referring to FIG. 3 and FIG. 7A, the incident light Li may be obliquely incident on the periphery 1100P of the pixel array 1100. For example, the incident light Li may be obliquely incident on the periphery 1100P on the right side of the pixel array 1100 from left to right. In particular, the incident light Li may be obliquely incident on the planar nano-optical microlens 131, the planar nano-optical microlens 132, the planar nano-optical microlens 133, and the planar nano-optical microlens 134 disposed at the periphery of the planar nano-optical microlens array 130. Accordingly, the planar nano-optical microlens 131, the planar nano-optical microlens 132, the planar nano-optical microlens 133, and the planar nano-optical microlens 134 disposed at the periphery 1100P of the pixel array 1100 may be configured to change a travel direction of the obliquely incident light to be a nearly perpendicular direction. To this end, nanostructures in the planar nano-optical microlens 131, the planar nano-optical microlens 132, the planar nano-optical microlens 133, and the planar nano-optical microlens 134 disposed at the periphery 1100P of the pixel array 1100 may be arranged in an asymmetric distribution.

FIG. 7B is a plan view illustrating the shape of the planar nano-optical microlens 131 shown in FIG. 7A. In FIG. 7B, for convenience of explanation, the planar nano-optical microlens 131 is described as an example, but the descriptions below may be similarly applied to the other ones of the planar nano-optical microlenses 132, the planar nano-optical microlenses 133, and the planar nano-optical microlenses 134. In addition, FIG. 7B shows that three planar nano-optical microlenses 131 are successively arranged, but the other of the planar nano-optical microlenses 132, the planar nano-optical microlenses 133, and the planar nano-optical microlenses 134 may be provided between two adjacent planar nano-optical microlenses 131. The three planar nano-optical microlenses 131 shown in FIG. 7B are provided at different positions in the first direction so that CRAs of incident light may be different from each other.

Referring to FIG. 7B, widths or diameters of the plurality of high refractive index nanostructures 131H within each planar nano-optical microlens 131 may be asymmetrically distributed in consideration of a CRA. For example, the high refractive index nanostructure 131H with the greatest width or diameter within each planar nano-optical microlens 131 may be positioned off toward the center 1100C of the pixel array 1100 from the center of the planar nano-optical microlens 131. In other words, the high refractive index nanostructure 131H with the greatest width or diameter within the planar nano-optical microlens 131 may be disposed biased toward the center 1100C of the pixel array 1100. The CRA increases further away from the center 1100C of the pixel array 1100, and thus, widths or diameters of the plurality of high refractive index nanostructures 131H within the planar nano-optical microlens 131 may be more asymmetrically distributed further away from the center 1100C of the pixel array 1100 For example, the further the planar nano-optical microlens 131 is disposed from the center 1100C of the pixel array 1100, the greater the distance between a position of the high refractive index nanostructure 131H with the greatest width or diameter within the planar nano-optical microlens 131 and the center of the planar nano-optical microlens 131 may increase.

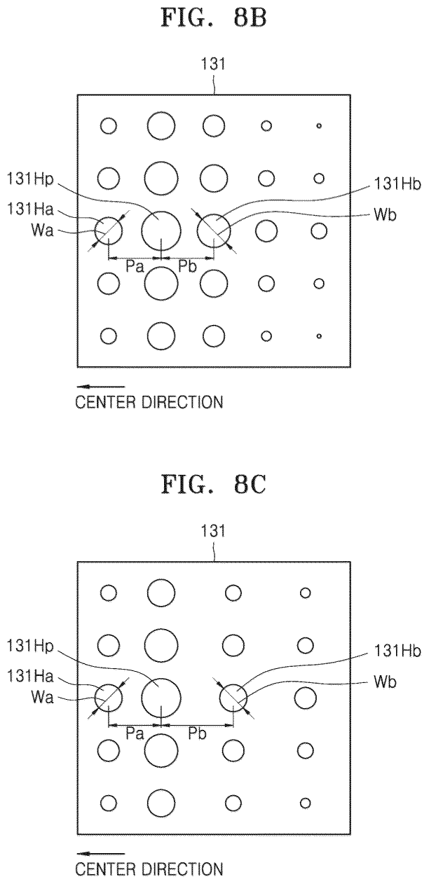

However, the further the planar nano-optical microlens 131 is disposed from the center 1100C of the pixel array 1100, the greater the distance between a position of the high refractive index nanostructure 131H with the greatest width or diameter within the planar nano-optical microlens 131 and the center of the planar nano-optical microlens 131 does not necessarily increase, and the high refractive index nanostructure 131H may be provided such that at the periphery of the planar nano-optical microlens array 130, the greater the distance between the planar nano-optical microlens 131 and the center of the planar nano-optical microlens array 130 increases, the greater the distance between the peak of the phase profile of the transmitted light and the center of the planar nano-optical microlens 131 increases. FIG. 8A is a plan view illustrating an effective refractive index distribution of planar nano-optical microlens 131 shown in FIG. 7A. Referring to FIG. 8A, the planar nano-optical microlens 131, the planar nano-optical microlens 132, the planar nano-optical microlens 133, and the planar nano-optical microlens 134 disposed at the periphery 1100P of the pixel array 1100 may include the first area 131a disposed offset from the center of the planar nano-optical microlens 131, the planar nano-optical microlens 132, the planar nano-optical microlens 133, and the planar nano-optical microlens 134, the second area 131b adjacent to the first area 131a and surrounding the first area 131a, the third area 131c adjacent to the second area 131b and surrounding the second area 131b, the fourth area 131d adjacent to the third area 131c and surrounding the third area 131c, and the fifth area 131e adjacent to the fourth area 131d and surrounding the fourth area 131d. The first area 131a is a refractive index peak area with the greatest effective refractive index. In other words, a ratio of the high refractive index nanostructure 131H to the low refractive index structure 131L is the greatest in the first area 131a. The effective refractive index may gradually decrease from the first area 131a to the fifth area 131e. Accordingly, the effective refractive index distribution within each planar nano-optical microlens 131 disposed in the periphery 1100P of the pixel array 1100 may be asymmetrical. The plurality of high refractive index nanostructures 131H within each planar nano-optical microlens 131 may be designed so that each planar nano-optical microlens 131 implements the effective refractive index distribution as shown in FIG. 8A.

For example, the high refractive index nanostructure 131H with the greatest width or diameter may be disposed within the first area 131a which is a refractive index peak area within the planar nano-optical microlens 131. Widths or diameters of the plurality of high refractive index nanostructures 131H within each planar nano-optical microlens 131 may be asymmetrically distributed with respect to the first area 131a, the refractive index peak area, or the high refractive index nanostructure 131H with the greatest width or diameter. For example, referring to FIG. 8B, among two high refractive index nanostructures directly adjacent to the high refractive index nanostructure 131H (hereinafter, “peak high refractive index nanostructure 131Hp”) with the greatest width or diameter, when the high refractive index nanostructure 131H closer to the center 1100C of the pixel array 1100 is referred to as a first high refractive index nanostructure 131Ha, and the high refractive index nanostructure 131H farther from the center 1100C of the pixel array 1100 is referred to as a second high refractive index nanostructure 131Hb, a first pitch Pa between the peak high refractive index nanostructure 131Hp and the first high refractive index nanostructure 131Ha may be the same as a second pitch Pb between the peak high refractive index nanostructure 131Hp and the second high refractive index nanostructure 131Hb, and a width or diameter Wa of the first high refractive index nanostructure 131 Ha may be different from a width or diameter Wb of the second high refractive index nanostructure 131Hb. For example, the width or diameter Wa of the first high refractive index nanostructure 131Ha may be less than the width or diameter Wb of the second high refractive index nanostructure 131Hb.

According to one or more embodiments, as shown in FIG. 8C, the width or diameter Wa of the first high refractive index nanostructure 131Ha may be the same as the width or diameter Wb of the second high refractive index nanostructure 131Hb, and the first pitch Pa between the peak high refractive index nanostructure 131Hp and the first high refractive index nanostructure 131Ha may be different from the second pitch Pb between the peak high refractive index nanostructure 131Hp and the second high refractive index nanostructure 131Hb. For example, the first pitch Pa may be less than the second pitch Pb. Here, the expression “the width or diameter Wa of the first high refractive index nanostructure 131Ha is the same as the width or diameter Wb of the second high refractive index nanostructure 131Hb” does not necessarily mean that the width or diameter Wa of the first high refractive index nanostructure 131Ha perfectly matches the width or diameter Wb of the second high refractive index nanostructure 131Hb. For example, the first high refractive index nanostructure 131Ha and the second high refractive index nanostructure 131Hb may be designed so that the width or diameter Wa of the first high refractive index nanostructure 131Ha and the width or diameter Wb of the second high refractive index nanostructure 131Hb are the same as each other, the width or diameter Wa of the first high refractive index nanostructure 131Ha and the width or diameter Wb of the second high refractive index nanostructure 131Hb may slightly vary within the tolerance of a manufacturing process.

In addition, referring again to FIG. 8A, the first area 131a, which is the refractive index peak area, within the planar nano-optical microlens 131 may be disposed biased toward the center 1100C of the pixel array 1100. As the planar nano-optical microlens 131 is disposed further away from the center 1100C of the pixel array 1100, the refractive index peak area within the planar nano-optical microlens 131 may be disposed more biased toward the center 1100C of the pixel array 1100. In other words, the further away the planar nano-optical microlens 131 is disposed from the center 1100C of the pixel array 1100, a distance between a position of the refractive index peak area within the planar nano-optical microlens 131 and the center of the planar nano-optical microlens 131 may further increase. In addition, the center of each of the first area 131a to the fifth area 131e may be shifted so that the center of the first area 131a is closest to the center of the pixel array 1100 and a distance from the center of the pixel array 1100 to the center of the fifth area 131e is the greatest.

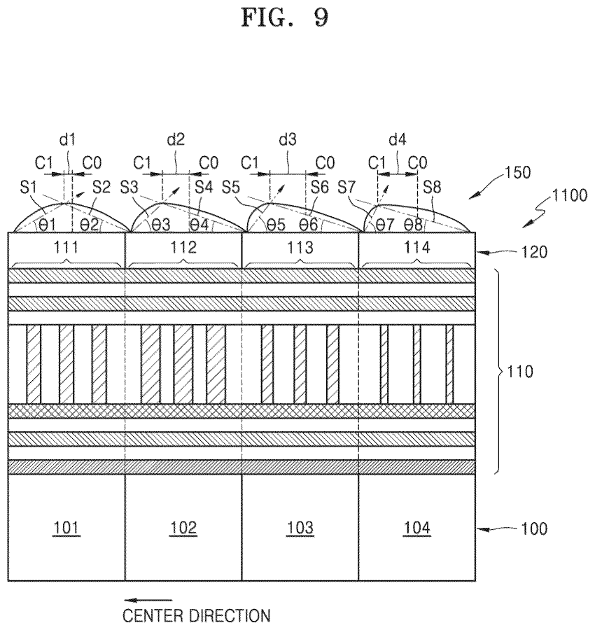

FIG. 9 is a cross-sectional view showing a phase profile of light immediately after transmitting through the planar nano-optical microlens 131 shown in FIG. 7A. A curve displayed on the hyperspectral filter array 110 in FIG. 9 indicates the phase profile of light immediately after transmitting through each planar nano-optical microlens 131. A height of the curve displayed on the hyperspectral filter array 110 in FIG. 9 may be interpreted as a normalized value of the phase profile of light transmitted through each planar nano-optical microlens 131.

Referring to FIG. 9, a phase profile peak C1 in the planar nano-optical microlens 131 disposed at the periphery 1100P of the pixel array 1100 may be positioned off toward the center 1100C of the pixel array 1100 from a center C0 of the planar nano-optical microlens 131, the planar nano-optical microlens 132, the planar nano-optical microlens 133, and the planar nano-optical microlens 134. Therefore, a distance between a first edge (left) of the planar nano-optical microlens 131 on the side closest to the center 1100C of the pixel array 1100 and the phase profile peak C1 may be less than a distance between a second edge (right) of the planar nano-optical microlens 134 on the opposite side to the first edge and the phase profile peak C1.

Also, referring to FIG. 9, a phase profile of light transmitted through each of the planar nano-optical microlens 131, the planar nano-optical microlens 132, the planar nano-optical microlens 133, and the planar nano-optical microlens 134 disposed at the periphery 1100P of the pixel array 1100 may have an asymmetrical shape. In other words, phase profiles of both sides with respect to the phase profile peak C1 may be different from each other. For example, with respect to the phase profile peak C1, a phase profile change amount of a direction in which light is incident or the side close to the center 1100C of the pixel array 1100 (or an area between the first edge and the phase profile peak C1) may be greater than a phase profile change amount of the side away from the center 1100C of the pixel array 1100 (or an area between the second edge and the phase profile peak C1). In other words, with respect to the phase profile peak C1, the phase profile change amount of the direction in which light is incident or the side close to the center 1100C of the pixel array 1100 (or the area between the first edge and the phase profile peak C1) may be relatively rapid, and the phase profile change amount of the side away from the center 1100C of the pixel array 1100 (or the area between the second edge and the phase profile peak C1) may be relatively gentle. For example, an inclination or inclination angle θ1 of a first line segment S1 extending between a phase profile value of the first edge of the planar nano-optical microlens 131 disposed on the leftmost side in FIG. 9 and the refractive index peak C1 may be greater than an inclination or inclination angle θ2 of a second line segment S2 extending between a phase profile value of the second edge and the refractive index peak C1.

A distance between the center C0 of the planar nano-optical microlens 131, the planar nano-optical microlens 132, the planar nano-optical microlens 133, and the planar nano-optical microlens 134 and the phase profile peak C1 may increase, and the asymmetry of a phase distribution of transmitted light may increase further away from the center 1100C of the pixel array 1100. For example, a second distance d2 between the center C0 of the planar nano-optical microlens 132 disposed second from the left in FIG. 9 and the phase profile peak C1 is greater than a first distance d1 between the center C0 of the planar nano-optical microlens 131 disposed on the leftmost side in FIG. 9 and the phase profile peak C1, a third distance d3 between the center C0 of the planar nano-optical microlens 133 disposed second from the right in FIG. 9 and the phase profile peak C1 is greater than the second distance d2, and a fourth distance d4 between the center C0 of the planar nano-optical microlens 134 disposed on the rightmost side in FIG. 9 and the phase profile peaks C1 is greater than the third distance d3. In FIG. 9, v 132 and the planar nano-optical microlens 133 disposed in the middle are disposed farther from the center 1100C of the pixel array 1100 than the planar nano-optical microlens 131 disposed on the leftmost side. In FIG. 9, the planar nano-optical microlenses 133 and the planar nano-optical microlenses 134 disposed on the rightmost side are disposed farther from the center 1100C of the pixel array 1100 than the planar nano-optical microlenses 132 and the planar nano-optical microlenses 133 disposed in the middle.

And, an inclination or inclination angle θ3 of a third line segment S3 extending between a phase profile value of a first edge of the planar nano-optical microlens 132 disposed second from the left in FIG. 9 and the phase profile peak C1 is greater than the inclination or inclination angle θ1 of the first line segment S1, and an inclination or inclination angle θ5 of a fifth line segment S5 extending between a phase profile value of a first edge of the planar nano-optical microlens 133 disposed second from the right in FIG. 9 and the phase profile peak C1 is greater than the inclination or inclination angle θ3 of the third line segment S3. In addition, an inclination or inclination angle θ7 of a seventh line segment S7 extending between a phase profile value of the first edge of the planar nano-optical microlens 134 disposed on the rightmost side in FIG. 9 and the phase profile peak C1 is greater than the inclination or inclination angle θ5 of the fifth line segment S5. Accordingly, the inclination of the phase profile in the area between the first edge and the phase profile peak C1 may increase further away from the center 1100C of the pixel array 1100. In addition, an inclination or inclination angle θ4 of a fourth line segment S4 extending between a phase profile value of a second edge of the planar nano-optical microlens 132 disposed second from the left in FIG. 9 and the phase profile peak C1 is less than the inclination or inclination angle θ2 of the second line segment S2, and an inclination or inclination angle θ6 of a sixth line segment S6 extending between a phase profile of a second edge of each of the planar nano-optical microlens 131, the planar nano-optical microlens 132, the planar nano-optical microlens 133, and the planar nano-optical microlens 134 disposed second from the right in FIG. 9 and the phase profile peak C1 is less than the inclination or inclination angle θ4 of the fourth line segment S4. In addition, an inclination or inclination angle θ8 of an eighth line segment S8 extending between the phase profile value of the second edge of the planar nano-optical microlens 134 disposed on the rightmost side in FIG. 9 and the phase profile peak C1 is less than the inclination or inclination angle θ6 of the sixth line segment S6. Accordingly, an inclination of the phase profile in the area between the second edge and the phase profile peak C1 may decrease further away from the center 1100C of the pixel array 1100.

All of the planar nano-optical microlens 131, the planar nano-optical microlens 132, the planar nano-optical microlens 133, and the planar nano-optical microlens 134 within the planar nano-optical microlens array 130 may have different phase profiles according to the distance from the center 1100C of the pixel array 1100. In this case, the phase profile of light transmitted through the planar nano-optical microlens 131, the planar nano-optical microlens 132, the planar nano-optical microlens 133, and the planar nano-optical microlens 134 may almost continuously change as the distance from the center 1100C of the pixel array 1100 increases. Alternatively, the planar nano-optical microlens array 130 may be divided into a plurality of zones, and light transmitted through the planar nano-optical microlens 131, the planar nano-optical microlens 132, the planar nano-optical microlens 133, and the planar nano-optical microlens 134 disposed in the same zone may have the same phase profile.

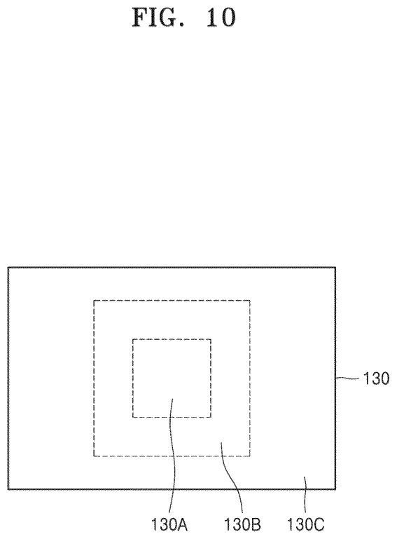

For example, FIG. 10 is a plan view schematically showing the first zone 130A, the second zone 130B, and the third zone 130C of the planar nano-optical microlens array 130 according to one or more embodiments.

Referring to FIG. 10, the planar nano-optical microlens array 130 may include the first zone 130A at the very center, the second zone 130B surrounding the first zone 130A, and the third zone 130C surrounding the second zone 130B. The first zone 130A may correspond to the center 1100C of the pixel array 1100. For example, a zone where a CRA of incident light is within about 10° may be defined as the center 1100C of the pixel array 1100. Accordingly, the center 1100C of the pixel array 1100 may include not only a zone where the CRA is strictly 0°, but also a zone where the CRA is slightly greater than 0° within a certain range. In this case, the planar nano-optical microlens 131, the planar nano-optical microlens 132, the planar nano-optical microlens 133, and the planar nano-optical microlens 134 disposed in the first zone 130A may all have a symmetrical effective refractive index distribution.

A CRA of the incident light in the second zone 130B may be, for example, greater than about 10° and within about 20°. The planar nano-optical microlens 131, the planar nano-optical microlens 132, the planar nano-optical microlens 133, and the planar nano-optical microlens 134 disposed in the second zone 130B may all have the same asymmetrical effective refractive index distribution. In addition, a CRA of the incident light in the third zone 130C may be greater than, for example, about 20°. The planar nano-optical microlens 131, the planar nano-optical microlens 132, the planar nano-optical microlens 133, and the planar nano-optical microlens 134 disposed in the third zone 130C may all have the same asymmetrical effective refractive index distribution, and a degree of asymmetry of the effective refractive index distribution of the planar nano-optical microlens 131, the planar nano-optical microlens 132, the planar nano-optical microlens 133, and the planar nano-optical microlens 134 disposed in the third zone 130C may be greater than a degree of asymmetry of the effective refractive index distribution of the planar nano-optical microlens 131, the planar nano-optical microlens 132, the planar nano-optical microlens 133, and the planar nano-optical microlens 134 disposed in the second zone 130B. Meanwhile, the effective refractive index distribution of the planar nano-optical microlens 131, the planar nano-optical microlens 132, the planar nano-optical microlens 133, and the planar nano-optical microlens 134 is not necessarily the same as FIG. 9, and the effective refractive index distribution of the planar nano-optical microlens 131 may be determined according to the phase profile illustrated in FIG. 9.

In addition, FIG. 10 illustrates that the planar nano-optical microlens array 130 is divided into three zones, but this is merely an example to aid understanding and the number of zones is not limited to three. In addition, a range of the CRA of incident light, which is reference for dividing a plurality of zones, may also be selected variously in consideration of the size and sensitivity of the hyperspectral image sensor 1000 and the optical characteristics of the lens assembly 1910.

The planar nano-optical microlens array 130 described above has a planar nanostructure, thereby easily determining an optical curvature profile of a lens surface compared to a microlens array with a curved surface. For example, by differently selecting the diameter, width, and pitch of each of the low refractive index structure 131L and the high refractive index nanostructure 131H according to the areas of the planar nano-optical microlens 131, the planar nano-optical microlens 132, the planar nano-optical microlens 133, and the planar nano-optical microlens 134, within individual ones of the planar nano-optical microlens 131, the planar nano-optical microlens 132, the planar nano-optical microlens 133, and the planar nano-optical microlens 134, the planar nano-optical microlens 131, the planar nano-optical microlens 132, the planar nano-optical microlens 133, and the planar nano-optical microlens 134 each having a phase profile of light transmitted through the desired planar nano-optical microlens may be easily designed. Therefore, the planar nano-optical microlens 131, the planar nano-optical microlens 132, the planar nano-optical microlens 133, and the planar nano-optical microlens 134 each having an optimal shape in accordance with the CRA of the incident light incident on the pixel array 1100 of the hyperspectral image sensor 1000 may be easily designed and manufactured. In addition, as described above, the planar nano-optical microlens array 130 may change an angle of incidence of incident light incident at a large CRA at the periphery 1100P of the pixel array 1100 of the hyperspectral image sensor 1000 to be nearly perpendicular. In particular, the planar nano-optical microlens array 130 may include the planar nano-optical microlens 131, the planar nano-optical microlens 132, the planar nano-optical microlens 133, and the planar nano-optical microlens 134 of various shapes in consideration of the change in the CRA according to several positions on the pixel array 1100 of the hyperspectral image sensor 1000. Accordingly, the sensitivity of pixels positioned in the periphery 1100P of the pixel array 1100 of the hyperspectral image sensor 1000 may be improved to be similar to the sensitivity of pixels positioned in the center 1100C of the pixel array 1100.

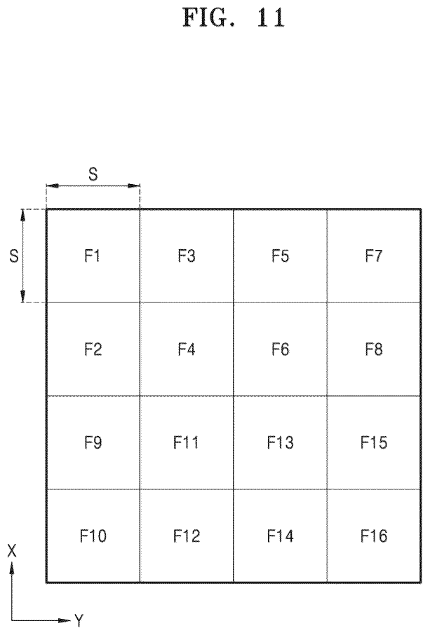

FIG. 11 is a plan view schematically showing an arrangement of a plurality of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter F16, of the hyperspectral filter array 110 according to one or more embodiments.

Referring to FIG. 11, the hyperspectral filter array 110 may include the plurality of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter F16 arranged in a two-dimensional form. For example, the hyperspectral filter array 110 may include sixteen types of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter 16, in a 4×4 arrangement. The sixteen types of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter 16, described above may have different transmission wavelength bands. The sixteen types of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter 16, in the 4×4 arrangement may be repeatedly arranged in the first direction (X direction) and the second direction (Y direction). However, the unit filters are not limited thereto, and band halters may be arranged in various forms. A size S of each of the unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter 16, may be, for example, approximately 0.4 μm to 100 μm, but is not limited thereto.

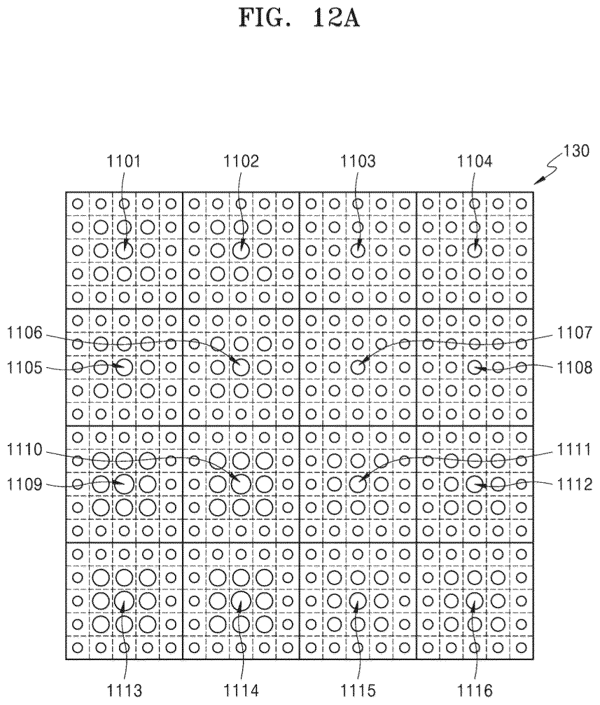

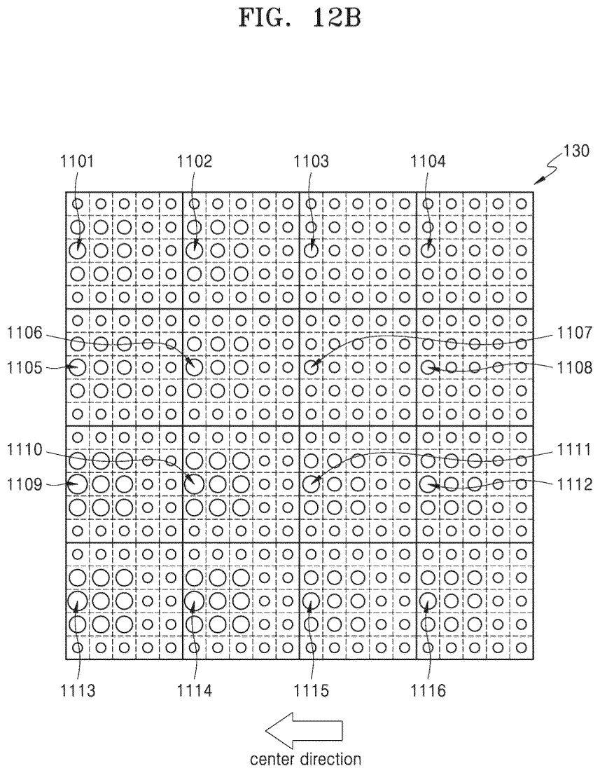

FIG. 12A and FIG. 12B are cross-sectional views showing a distribution of nanostructures of the planar nano-optical microlens array 130 provided on the plurality of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter 16, of the hyperspectral filter array 110 of FIG. 11.

Referring to FIG. 12A, in the hyperspectral image sensor 1000 that separates light of sixteen different wavelengths, the planar nano-optical microlens array 130 may include sixteen different types of planar nano-optical microlenses respectively corresponding to the unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit filter F13, the unit filter F14, the unit filter F15, and the unit filter F16, of the hyperspectral filter array 110. FIG. 12A shows only the sixteen planar nano-optical microlenses in a 4×4 arrangement, but the sixteen planar nano-optical microlenses in the 4×4 arrangement may be actually repeated multiple times in the first and second directions. Among a plurality of high refractive index nanostructures of the planar nano-optical microlens array 130, widths or diameters of the high refractive index nanostructure 1101, the high refractive index nanostructure 1102, the high refractive index nanostructure 1103, the high refractive index nanostructure 1104, the high refractive index nanostructure 1105, and the high refractive index nanostructure 1106, the high refractive index nanostructure 1107, the high refractive index nanostructure 1108, the high refractive index nanostructure 1109, the high refractive index nanostructure 1110, the high refractive index nanostructure 1111, and the high refractive index nanostructure 1112, the high refractive index nanostructure 1113, the high refractive index nanostructure 1114, the high refractive index nanostructure 1115, and the high refractive index nanostructure 1116 respectively disposed at the refractive index peak areas of the planar nano-optical microlenses may be different according to a center wavelength of a transmission band of the unit filter corresponding to each of the planar nano-optical microlenses. For example, the greater the center wavelength of the transmission band of the corresponding unit filter, the smaller the widths or diameters of the high refractive index nanostructure 1101, the high refractive index nanostructure 1102, the high refractive index nanostructure 1103, the high refractive index nanostructure 1104, the high refractive index nanostructure 1105, and the high refractive index nanostructure 1106, the high refractive index nanostructure 1107, the high refractive index nanostructure 1108, the high refractive index nanostructure 1109, the high refractive index nanostructure 1110, the high refractive index nanostructure 1111, and the high refractive index nanostructure 1112, the high refractive index nanostructure 1113, the high refractive index nanostructure 1114, the high refractive index nanostructure 1115, and the high refractive index nanostructure 1116 respectively disposed at the refractive index peak areas of the planar nano-optical microlenses. Alternatively, the greater the center wavelength of the transmission band of the corresponding unit filter, the smaller the widths or diameters of the high refractive index nanostructure 1101, the high refractive index nanostructure 1102, the high refractive index nanostructure 1103, the high refractive index nanostructure 1104, the high refractive index nanostructure 1105, and the high refractive index nanostructure 1106, the high refractive index nanostructure 1107, the high refractive index nanostructure 1108, the high refractive index nanostructure 1109, the high refractive index nanostructure 1110, the high refractive index nanostructure 1111, and the high refractive index nanostructure 1112, the high refractive index nanostructure 1113, the high refractive index nanostructure 1114, the high refractive index nanostructure 1115, and the high refractive index nanostructure 1116 having the greatest width or diameter among the plurality of high refractive index nanostructures in the plurality of planar nano-optical microlenses. In addition, periods of the plurality of high refractive index nanostructures of the planar nano-optical microlens array 130 may be different according to center wavelengths of transmission bands of the unit filters corresponding to the planar nano-optical microlenses. A distribution of the plurality of high refractive index nanostructures within the plurality of planar nano-optical microlenses is to ensure that light immediately after transmitting through the planar nano-optical microlenses has the phase profile shown in FIG. 5B.

Referring to FIG. 12B, among the plurality of high refractive index nanostructures of the planar nano-optical microlens array 130 positioned at the periphery of the pixel array of the hyperspectral image sensor, the high refractive index nanostructure 1101, the high refractive index nanostructure 1102, the high refractive index nanostructure 1103, the high refractive index nanostructure 1104, the high refractive index nanostructure 1105, and the high refractive index nanostructure 1106, the high refractive index nanostructure 1107, the high refractive index nanostructure 1108, the high refractive index nanostructure 1109, the high refractive index nanostructure 1110, the high refractive index nanostructure 1111, and the high refractive index nanostructure 1112, the high refractive index nanostructure 1113, the high refractive index nanostructure 1114, the high refractive index nanostructure 1115, and the high refractive index nanostructure 1116 respectively disposed at the refractive index peak areas of the planar nano-optical microlenses corresponding to the unit filters may be asymmetrically arranged as described in FIG. 7B. A distribution of the plurality of high refractive index nanostructures within the plurality of planar nano-optical microlenses is to ensure that light immediately after transmitting through the planar nano-optical microlenses has the asymmetrical phase profile as shown in FIG. 9.

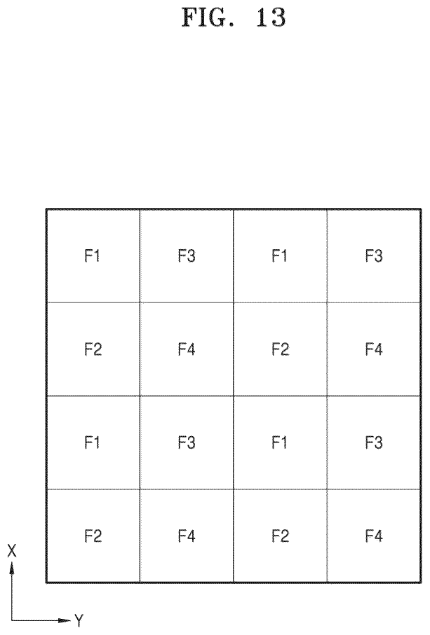

FIG. 13 is a plan view schematically showing of the plurality of the unit filter F1, the unit filter F2, the unit filter F3, and the unit filter F4 of the hyperspectral filter array 110 according to one or more embodiments.

Referring to FIG. 13, the hyperspectral filter array 110 may include the plurality of the unit filter F1, the unit filter F2, the unit filter F3, and the unit filter F4 arranged in a two-dimensional form. For example, the hyperspectral filter array 110 may include the four types of unit filters F1 to F4 arranged in the two-dimensional form. The four types of unit filters, the unit filter F1, the unit filter F2, the unit filter F3, the unit filter F4, the unit filter F5, the unit filter F6, the unit filter F7, the unit filter F8, the unit filter F9, the unit filter F10, the unit filter F11, the unit filter F12, the unit f described above may have different transmission wavelength bands. The four types of unit filters F1 to F4 arranged in the two-dimensional form may be repeatedly arranged in the first direction (X direction) and the second direction (Y direction). However, the unit filters are not limited thereto, and band halters may be arranged in various forms.

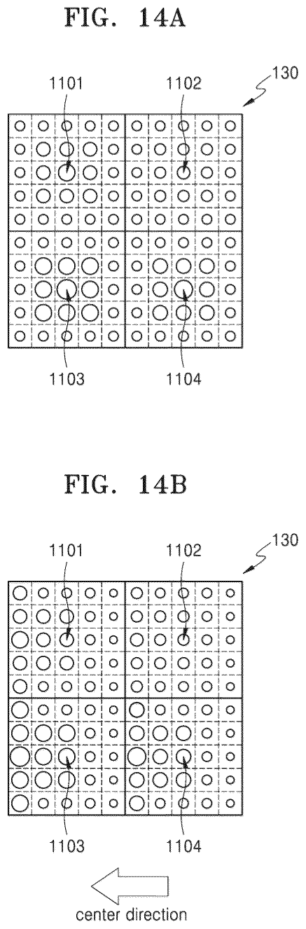

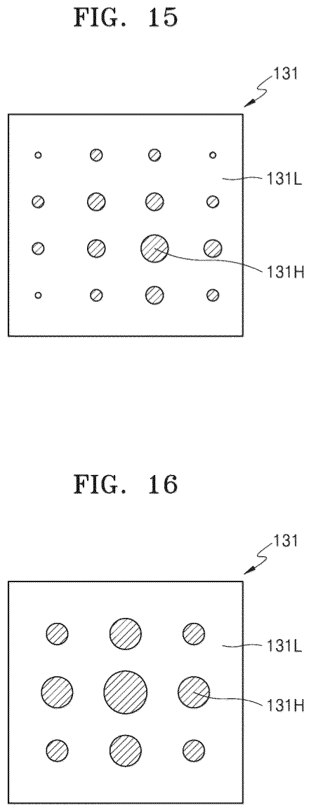

FIG. 14A and FIG. 14B are cross-sectional views showing a distribution of nanostructures of the planar nano-optical microlens array 130 provided on the plurality of the unit filter F1, the unit filter F2, the unit filter F3, and the unit filter F4 of the hyperspectral filter array 110 of FIG. 13.

Referring to FIG. 14A, in the hyperspectral image sensor 1000 that separates light of four different wavelengths, the planar nano-optical microlens array 130 may include four different types of planar nano-optical microlenses respectively corresponding to the unit filter F1, the unit filter F2, the unit filter F3, and the unit filter F4 of the hyperspectral filter array 110. FIG. 14A shows only the four planar nano-optical microlenses in a 2×2 arrangement, but the four planar nano-optical microlenses in the 2×2 arrangement may be actually repeated multiple times in the first and second directions. Among a plurality of high refractive index nanostructures of the planar nano-optical microlens array 130, widths or diameters of the high refractive index nanostructure 1101, the high refractive index nanostructure 1102, the high refractive index nanostructure 1103, and the high refractive index nanostructure 1104 respectively disposed at the refractive index peak areas of the planar nano-optical microlenses may be different according to a center wavelength of a transmission band of the unit filter corresponding to each of the planar nano-optical microlenses. For example, the smaller the widths or diameters of the high refractive index nanostructure 1101, the high refractive index nanostructure 1102, the high refractive index nanostructure 1103, and the high refractive index nanostructure 1104 respectively disposed at the refractive index peak areas of the planar nano-optical microlenses, the greater the center wavelength of the transmission band of the corresponding unit filter. Alternatively, the smaller the widths or diameters of the high refractive index nanostructure 1101, the high refractive index nanostructure 1102, the high refractive index nanostructure 1103, and the high refractive index nanostructure 1104 having the greatest width or diameter among the plurality of high refractive index nanostructures in the plurality of planar nano-optical microlenses, the greater the center wavelength of the transmission band of the corresponding unit filter. In addition, periods of the plurality of high refractive index nanostructures of the planar nano-optical microlens array 130 may be different according to center wavelengths of transmission bands of the unit filters corresponding to the planar nano-optical microlenses.

Referring to FIG. 14B, among the plurality of high refractive index nanostructures of the planar nano-optical microlens array 130 positioned at the periphery of the pixel array of the hyperspectral image sensor, the high refractive index nanostructure 1101, the high refractive index nanostructure 1102, the high refractive index nanostructure 1103, and the high refractive index nanostructure 1104 respectively disposed at the refractive index peak areas of the planar nano-optical microlenses corresponding to the unit filters may be asymmetrically arranged as described in FIG. 7B.

FIG. 15 is a plan view showing another example of the shape of the planar nano-optical microlens 131 shown in FIG. 5A. The differences from FIG. 5A are mainly described.

Referring to FIG. 15, the planar nano-optical microlens 131, the planar nano-optical microlens 132, the planar nano-optical microlens 133, and the planar nano-optical microlens 134 may include the high refractive index nanostructures 131H and the low refractive index structure 131L filled between the high refractive index nanostructures 131H, and the high refractive index nanostructures 131H may be provided in a 4×4 arrangement.

FIG. 16 is a plan view showing another example of the shape of the planar nano-optical microlens 131 shown in FIG. 5A. The differences from FIG. 5A are mainly described.

Referring to FIG. 16, the planar nano-optical microlens 131, the planar nano-optical microlens 132, the planar nano-optical microlens 133, and the planar nano-optical microlens 134 may include the high refractive index nanostructures 131H and the low refractive index structure 131L filled between the high refractive index nanostructures 131H, and the high refractive index nanostructures 131H may be provided in a 3×3 arrangement.

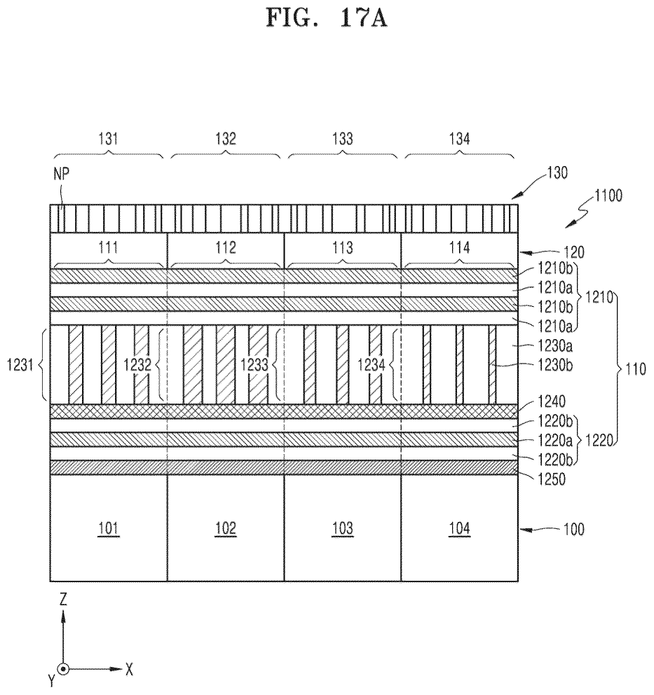

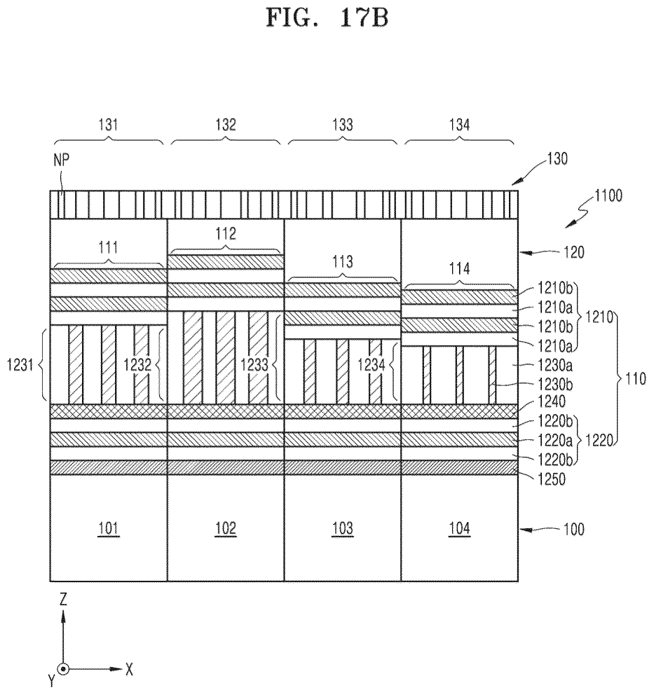

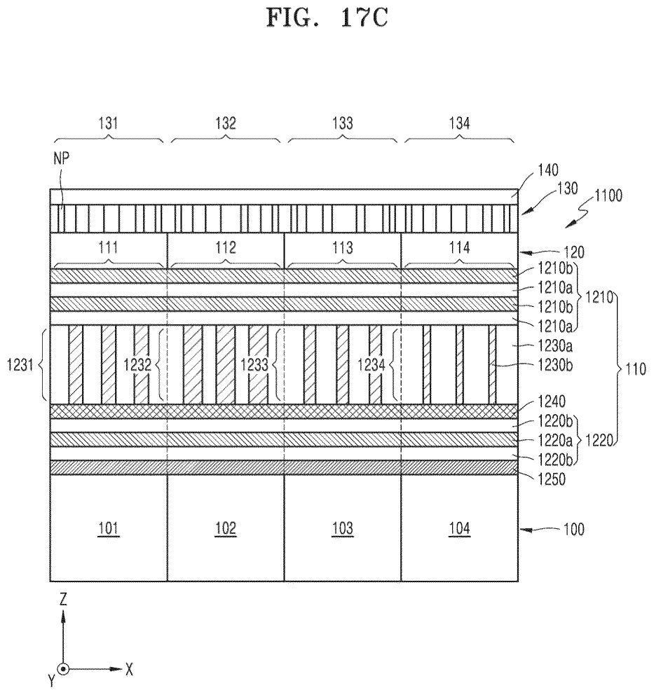

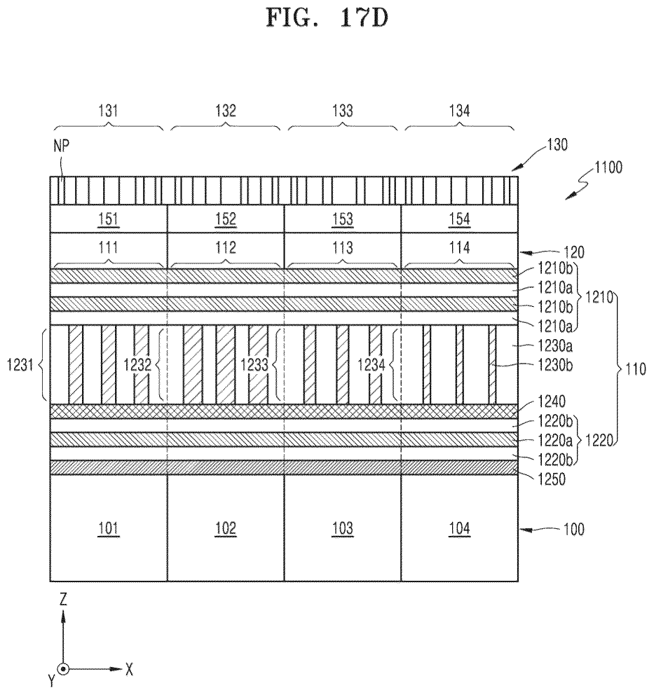

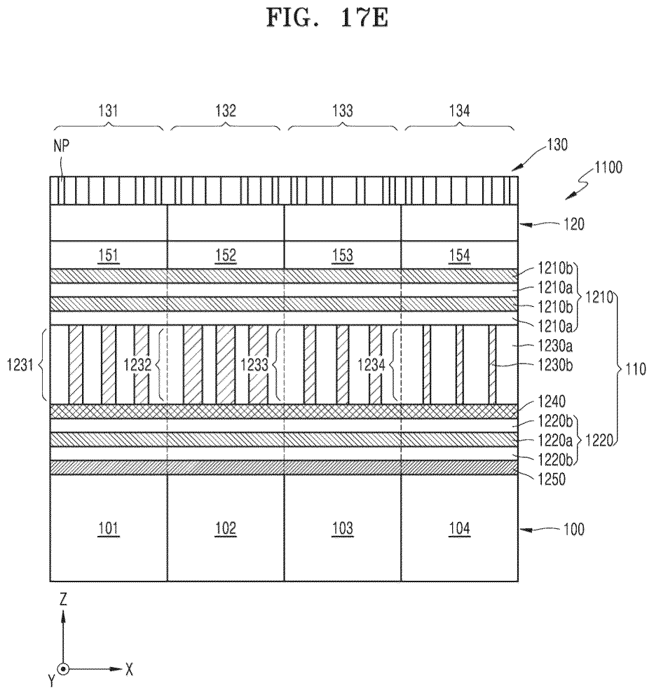

FIG. 17A, FIG. 17B, FIG. 17C, FIG. 17D, and FIG. 17E are cross-sectional views illustrating the pixel array 1100 of the hyperspectral image sensor 1000 shown in FIG. 4A according to one or more embodiments. The differences from FIG. 4A are mainly described.

Referring to FIG. 17A, the first cavity 1231, the second cavity 1232, the third cavity 1233, and the fourth cavity 1234 may each include certain dielectric patterns 1230a and 1230b. The first cavity 1231, the second cavity 1232, the third cavity 1233, and the fourth cavity 1234 may each include the first dielectric 1230a and the second dielectric 1230b disposed on the first dielectric 1230a. Here, a refractive index of the second dielectric 1230b may be greater than a refractive index of the first dielectric 1230a. As a specific example, the first dielectric 1230a may include silicon oxide, and the second dielectric 1230b may include titanium oxide. However, this is merely an example. Widths of the first dielectric 1230a of the first cavity 1231, the second cavity 1232, the third cavity 1233, and the fourth cavity 1234 may be different from each other, and widths of the second dielectric 1230b may be different from each other. Resonance wavelengths of the first cavity 1231, the second cavity 1232, the third cavity 1233, and the fourth cavity 1234 may be determined by the widths of the first dielectric 1230a and the widths of the second dielectric 1230b.

Referring to FIG. 17B, when thickness of the first cavity 1231, the second cavity 1232, the third cavity 1233, and the fourth cavity 1234 respectively provided in the first unit filter 111, the second unit filter 112, the third unit filter 113, and the fourth unit filter 114 are different, a thickness of the buffer layer 120 stacked on the first unit filter 111, the second unit filter 112, the third unit filter 113, and the fourth unit filter 114 may be different for each of the first unit filter 111, the second unit filter 112, the third unit filter 113, and the fourth unit filter 114. The sum of the thicknesses of the first cavity 1231, the second cavity 1232, the third cavity 1233, and the fourth cavity 1234 and the thickness of the buffer layer 120 for each of the first unit filter 111, the second unit filter 112, the third unit filter 113, and the fourth unit filter 114 may be constant. A level of a lower surface of the buffer layer 120 in the third direction (Z direction) may be different for each of the first unit filter 111, the second unit filter 112, the third unit filter 113, and the fourth unit filter 114, but a level of an upper surface of the buffer layer 120 in the third direction (Z direction) may be the same or similar in the first unit filter 111, the second unit filter 112, the third unit filter 113, and the fourth unit filter 114. The upper surface of the buffer layer 120 is flat so that the planar nano-optical microlens array 130 may be disposed on an upper portion of the buffer layer 120.

Referring to FIG. 17C, an anti-reflection film 140 may be provided on the planar nano-optical microlens array 130.

Referring to FIG. 17D and FIG. 17E, a plurality of the band blocking filter 151, the band blocking filter 152, he band blocking filter 153, and he band blocking filter 154 may be additionally provided between the hyperspectral filter array 110 and the buffer layer 120 or between the buffer layer 120 and the planar nano-optical micro lens array 130. Each of the band blocking filter 151, the band blocking filter 152, he band blocking filter 153, and he band blocking filter 154 may transmit only light in a specific wavelength band and absorb or reflect light in other wavelength bands. When a transmission spectrum of each of the first cavity 1231, the second cavity 1232, the third cavity 1233, and the fourth cavity 1234 provided in the hyperspectral filter array 110 has two peaks, a blocking band of each of the band blocking filter 151, the band blocking filter 152, he band blocking filter 153, and he band blocking filter 154 may be selected to remove a smaller peak. The band blocking filter 151, the band blocking filter 152, he band blocking filter 153, and he band blocking filter 154 may correspond one-to-one to the first unit filter 111, the second unit filter 112, the third unit filter 113, and the fourth unit filter 114.

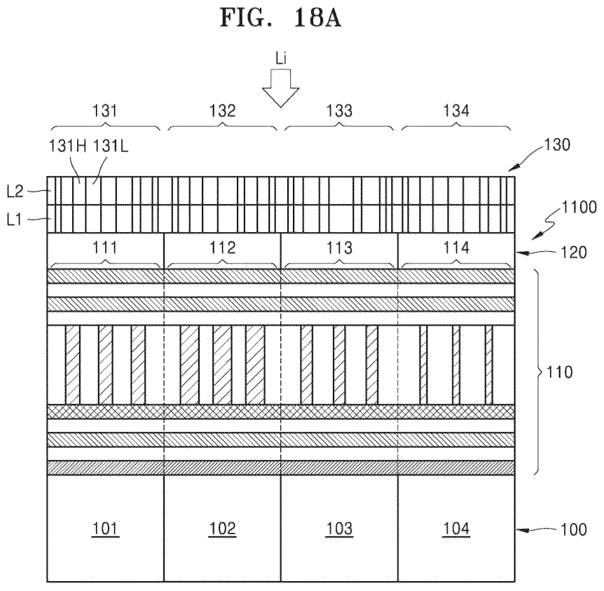

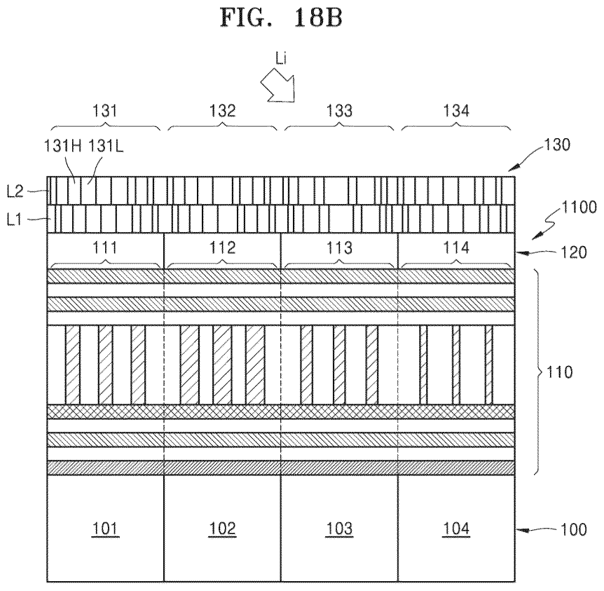

FIG. 18A and FIG. 18B are cross-sectional views showing shapes of the planar nano-optical microlens 131, the planar nano-optical microlens 132, the planar nano-optical microlens 133, and the planar nano-optical microlens 134 according to one or more embodiments.

As shown in FIG. 18A and FIG. 18B, the planar nano-optical microlens 131, the planar nano-optical microlens 132, the planar nano-optical microlens 133, and the planar nano-optical microlens 134 may have a multi-layer structure. For example, the planar nano-optical microlens 131, the planar nano-optical microlens 132, the planar nano-optical microlens 133, and the planar nano-optical microlens 134 may each include a first layer L1 and a second layer L2 stacked on the first layer L1. The first layer L1 and the second layer L2 may each include the high refractive index nanostructure 131H and the low refractive index structure 131L, and a pattern of each of the high refractive index nanostructure 131H and the low refractive index structure 131L of the first layer L1 may be different from a pattern of each of the high refractive index nanostructure 131H and the low refractive index structure 131L of the second layer L2. An effective refractive index of each area of the planar nano-optical microlens 131, the planar nano-optical microlens 132, the planar nano-optical microlens 133, and the planar nano-optical microlens 134 each having the multi-layer structure may be determined by synthesizing the high refractive index nanostructure 131H in the first layer L1 and the second layer L2 and the low refractive index structure 131L in the first layer L1 and the second layer L2.

Referring to FIG. 18A, in the planar nano-optical microlens 131, the planar nano-optical microlens 132, the planar nano-optical microlens 133, and the planar nano-optical microlens 134 disposed at the center of the pixel array 1100 where the incident light Li is perpendicularly incident, both the first layer L1 and the second layer L2 may have a symmetrical shape with respect to the center of the planar nano-optical microlens 131, the planar nano-optical microlens 132, the planar nano-optical microlens 133, and the planar nano-optical microlens 134. At the center of the planar nano-optical microlens 131, the planar nano-optical microlens 132, the planar nano-optical microlens 133, and the planar nano-optical microlens 134, the high refractive index nanostructures 131H of the first layer L1 and the second layer L2 may have the same width, but at the periphery of the planar nano-optical microlens 131, the planar nano-optical microlens 132, the planar nano-optical microlens 133, and the planar nano-optical microlens 134, a width of the high refractive index nanostructure 131H of the second layer L2 where light is first incident may be smaller than a width of the high refractive index nanostructure 131H of the first layer L1 disposed therebelow. In addition, the effective refractive index of the planar nano-optical microlens 131, the planar nano-optical microlens 132, the planar nano-optical microlens 133, and the planar nano-optical microlens 134 determined by synthesizing the first layer L1 and the second layer L2 may be the greatest near the center and may gradually decrease toward the periphery of a refractive index peak area.

However, at the periphery, the width of the high refractive index nanostructure 131H of the second layer L2 where light is first incident is not necessarily relatively smaller than the width of the high refractive index nanostructure 131H of the first layer L1 disposed therebelow, and the width of the high refractive index nanostructure 131H of the first layer L1 and the width of the high refractive index nanostructure 131H of the second layer L2 may be determined according to a phase profile to be implemented. That is, the width of the high refractive index nanostructure 131H of each of the first layer L1 and the second layer L2 may be determined so that a phase profile of light transmitted through the first layer L1 and a phase profile of a light transmitted through the second layer L2 are different.

Also, referring to FIG. 18B, in the planar nano-optical microlens 131, the planar nano-optical microlens 132, the planar nano-optical microlens 133, and the planar nano-optical microlens 134 disposed on the periphery 1100P of the pixel array 1100 where the incident light Li is obliquely incident, both the first layer L1 and the second layer L2 may have an asymmetrical shape with respect to the center of the planar nano-optical microlens 131, the planar nano-optical microlens 132, the planar nano-optical microlens 133, and the planar nano-optical microlens 134. For example, the refractive index peak area of the planar nano-optical microlens 131, the planar nano-optical microlens 132, the planar nano-optical microlens 133, and the planar nano-optical microlens 134 may be positioned biased from the center of the planar nano-optical microlens 131, the planar nano-optical microlens 132, the planar nano-optical microlens 133, and the planar nano-optical microlens 134 toward a direction in which light is incident or toward the center of the pixel array 1100. The effective refractive index of the planar nano-optical microlens 131, the planar nano-optical microlens 132, the planar nano-optical microlens 133, and the planar nano-optical microlens 134 determined by synthesizing the first layer L1 and the second layer L2 may be the greatest in the refractive index peak area and may gradually decrease toward the periphery of the refractive index peak area. In addition, the second layer L2 may be shifted toward the center of the pixel array 1100 with respect to the first layer L1.

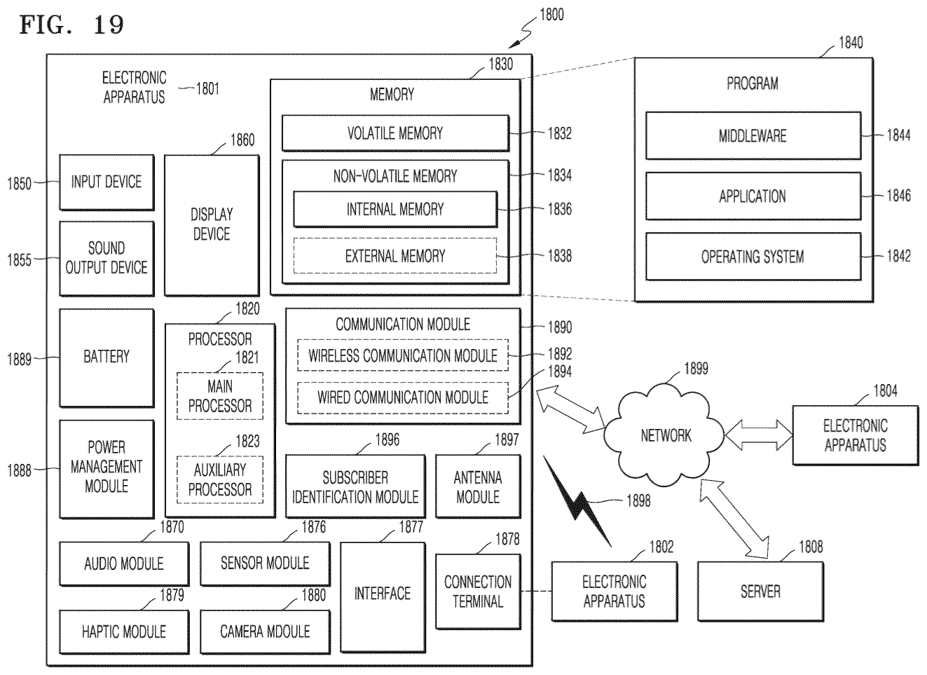

FIG. 19 is a block diagram illustrating an example of an electronic apparatus 1801 including the hyperspectral image sensor 1000.

Referring to FIG. 19, in a network environment 1800, the electronic apparatus 1801 may communicate with another electronic apparatus 1802 over a first network 1898 (short-range wireless communication network, etc.), or may communicate with another electronic apparatus 1804 and/or a server 1808 over a second network 1899 (long-range wireless communication network, etc.) The electronic apparatus 1801 may communicate with the electronic apparatus 1804 through the server 1808. The electronic apparatus 1801 may include a processor 1820, a memory 1830, an input device 1850, a sound output device 1855, a display device 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. In the electronic apparatus 1801, some (display device 1860, etc.) of components may be omitted or another component may be added. Some of the components may be configured as one integrated circuit. For example, the sensor module 1876 (a fingerprint sensor, an iris sensor, an illuminance sensor, etc.) may be embedded and implemented in the display device 1860 (display, etc.)

The processor 1820 may control one or more components (hardware and software components, etc.) of the electronic apparatus 1801 connected to the processor 1820 by executing software (program 1840, etc.), and may perform various data processes or operations. As a part of the data processes or operations, the processor 1820 may load a command and/or data received from another component (sensor module 1876, communication module 1890, etc.) to a volatile memory 1832, may process the command and/or data stored in the volatile memory 1832, and may store result data in a non-volatile memory 1834. The processor 1820 may include a main processor 1821 (central processing unit, application processor, etc.) and an auxiliary processor 1823 (graphic processing unit, image signal processor, sensor hub processor, communication processor, etc.) that may be operated independently from or along with the main processor 1821. The auxiliary processor 1823 may use less power than that of the main processor 1821, and may perform specified functions.

The auxiliary processor 1823, on behalf of the main processor 1821 while the main processor 1821 is in an inactive state (sleep state) or along with the main processor 1821 while the main processor 1821 is in an active state (application executed state), may control functions and/or states related to some (display device 1860, sensor module 1876, communication module 1890, etc.) of the components of the electronic apparatus 1801. The auxiliary processor 1823 (image signal processor, communication processor, etc.) may be implemented as a part of another component (camera module 1880, communication module 1890, etc.) that is functionally related thereto.

The memory 1830 may store various data required by the components (processor 1820, sensor module 1876, etc.) of the electronic apparatus 1801. The data may include, for example, input data and/or output data about software (program 1840, etc.) and commands related thereto. The memory 1830 may include the volatile memory 1832 and/or the non-volatile memory 1834.

The program 1840 may be stored as software in the memory 1830, and may include an operation system 1842, middleware 1844, and/or an application 1846.

The input device 1850 may receive commands and/or data to be used in the components (processor 1820, etc.) of the electronic apparatus 1801, from outside (user, etc.) of the electronic apparatus 1801. The input device 1850 may include a microphone, a mouse, a keyboard, and/or a digital pen (stylus pen).

The sound output device 1855 may output a sound signal to outside of the electronic apparatus 1801. The sound output device 1855 may include a speaker and/or a receiver. The speaker may be used for a general purpose such as multimedia reproduction or record play, and the receiver may be used to receive a call. The receiver may be coupled as a part of the speaker or may be implemented as an independent device.

The display device 1860 may provide visual information to outside of the electronic apparatus 1801. The display device 1860 may include a display, a hologram device, or a projector, and a control circuit for controlling the corresponding device. The display device 1860 may include a touch circuitry set to sense a touch, and/or a sensor circuit (pressure sensor, etc.) that is set to measure a strength of a force generated by the touch.

The audio module 1870 may convert sound into an electrical signal or vice versa. The audio module 1870 may acquire sound through the input device 1850, or may output sound through the sound output device 1855 and/or a speaker and/or a headphone of another electronic apparatus (electronic apparatus 1802, etc.) connected directly or wirelessly to the electronic apparatus 1801.

The sensor module 1876 may sense an operating state (power, temperature, etc.) of the electronic apparatus 1801, or an outer environmental state (user state, etc.), and may generate an electrical signal and/or data value corresponding to the sensed state. The sensor module 1876 may include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, and/or an illuminance sensor.

The interface 1877 may support one or more designated protocols that may be used in order for the electronic apparatus 1801 to be directly or wirelessly connected to another electronic apparatus (electronic apparatus 1802, etc.) The interface 1877 may include a high-definition multimedia interface (HDMI), a universal serial bus (USB) interface, an SD card interface, and/or an audio interface.

The connection terminal 1878 may include a connector by which the electronic apparatus 1801 may be physically connected to another electronic apparatus (electronic apparatus 1802, etc.) The connection terminal 1878 may include an HDMI connector, a USB connector, an SD card connector, and/or an audio connector (headphone connector, etc.)

The haptic module 1879 may convert the electrical signal into a mechanical stimulation (vibration, motion, etc.) or an electric stimulation that the user may sense through a tactile or motion sensation. The haptic module 1879 may include a motor, a piezoelectric device, and/or an electric stimulus device.

The camera module 1880 may capture a still image and a video. The camera module 1880 may include a lens assembly including one or more lenses, the hyperspectral image sensor 1000 of FIG. 1, image signal processors, and/or flashes. The lens assembly included in the camera module 1880 may collect light emitted from an object that is an object to be captured.

The power management module 1888 may manage the power supplied to the electronic apparatus 1801. The power management module 1888 may be implemented as a part of a power management integrated circuit (PMIC).

The battery 1889 may supply electric power to the components of the electronic apparatus 1801. The battery 1889 may include a primary battery that is not rechargeable, a secondary battery that is rechargeable, and/or a fuel cell.

The communication module 1890 may support the establishment of a direct (wired) communication channel and/or a wireless communication channel between the electronic apparatus 1801 and another electronic apparatus (electronic apparatus 1802, electronic apparatus 1804, server 1808, etc.), and execution of communication through the established communication channel. The communication module 1890 may be operated independently from the processor 1820 (application processor, etc.), and may include one or more communication processors that support the direct communication and/or the wireless communication. The communication module 1890 may include a wireless communication module 1892 (cellular communication module, a short-range wireless communication module, a global navigation satellite system (GNSS) communication module) and/or a wired communication module 1894 (local area network (LAN) communication module, a power line communication module, etc.) From among the communication modules, a corresponding communication module may communicate with another electronic apparatus over a first network 1809 (short-range communication network such as Bluetooth, WiFi direct, or infrared data association (IrDA)) or a second network 1899 (long-range communication network such as a cellular network, Internet, or computer network (LAN, WAN, etc.)). Such above various kinds of communication modules may be integrated as one component (single chip, etc.) or may be implemented as a plurality of components (a plurality of chips) separately from one another. The wireless communication module 1892 may identify and authenticate the electronic apparatus 1801 in a communication network such as the first network 1898 and/or the second network 1899 by using subscriber information (international mobile subscriber identifier (IMSI), etc.) stored in the subscriber identification module 1896.

The antenna module 1897 may transmit or receive the signal and/or power to/from outside (another electronic apparatus, etc.) An antenna may include a radiator formed as a conductive pattern formed on a substrate (PCB, etc.) The antenna module 1897 may include one or more antennas. When the antenna module 1897 includes a plurality of antennas, from among the plurality of antennas, an antenna that is suitable for the communication type used in the communication network such as the first network 1898 and/or the second network 1899 may be selected by the communication module 1890. The signal and/or the power may be transmitted between the communication module 1890 and another electronic apparatus through the selected antenna. Another component (RFIC, etc.) other than the antenna may be included as a part of the antenna module 1897.

Some of the components may be connected to one another by using the communication method among the peripheral devices (bus, general purpose input and output (GPIO), serial peripheral interface (SPI), mobile industry processor interface (MIPI), etc.) and may exchange signals (commands, data, etc.)

The command or data may be transmitted or received between the electronic apparatus 1801 and the external electronic apparatus 1804 through the server 1808 connected to the second network 1899. The electronic apparatus 1802 and the electronic apparatus 1804 may be the same kind as or different kinds from that of the electronic apparatus 1801. All or some of the operations executed by the electronic apparatus 1801 may be executed by one or more apparatuses among the electronic apparatus 1802, the electronic apparatus 1804, and the server 1808. For example, when the electronic apparatus 1801 has to perform a certain function or service, the electronic apparatus 1801 may request one or more other electronic apparatuses to perform some or entire function or service, instead of executing the function or service by itself. One or more electronic apparatuses receiving the request execute an additional function or service related to the request and may transfer a result of the execution to the electronic apparatus 1801. To this end, cloud computing, distributed computing, or client-server computing technique may be used.

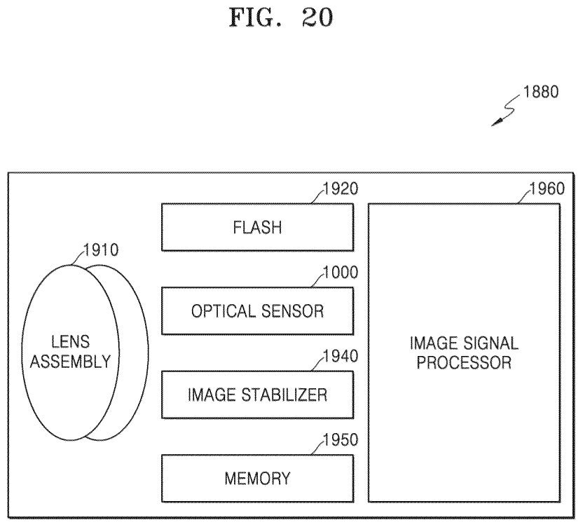

FIG. 20 is a block diagram schematically illustrating the camera module 1880 of FIG. 19.

Referring to FIG. 20, the camera module 1880 may include a lens assembly 1910, a flash 1920, the hyperspectral image sensor 1000 (see FIG. 1), an image stabilizer 1940, a memory 1950 (buffer memory, etc.), and/or an image signal processor 1960. The lens assembly 1910 may collect light emitted from an object that is to be captured. The camera module 1880 may include a plurality of lens assemblies 1910, and in this case, the camera module 1880 may include a dual camera module, a 360-degree camera, or a spherical camera. Some of the plurality of lens assemblies 1910 may have the same lens properties (viewing angle, focal distance, auto-focus, F number, optical zoom, etc.) or different lens properties. The lens assembly 1910 may include a wide-angle lens or a telephoto lens.

The flash 1920 may emit light that is used to strengthen the light emitted or reflected from the object. The flash 1920 may include one or more light-emitting diodes (red-green-blue (RGB) LED, white LED, infrared LED, ultraviolet LED, etc.), and/or a Xenon lamp. The hyperspectral image sensor 1000 may be the image sensor described above with reference to FIG. 1, and converts the light emitted or reflected from the object and transferred through the lens assembly 1910 into an electrical signal to obtain an image corresponding to the object. The hyperspectral image sensor 1000 may include one or a plurality of sensors selected from the image sensors having different properties, such as an RGB sensor, a black and white (BW) sensor, an IR sensor, or a UV sensor. Each of sensors included in the hyperspectral image sensor 1000 may be implemented as a charge coupled device (CCD) sensor and/or a complementary metal oxide semiconductor (CMOS) sensor.

The image stabilizer 1940, in response to a motion of the camera module 1880 or the electronic apparatus 1901 including the camera module 1880, moves one or more lenses included in the lens assembly 1910 or the hyperspectral image sensor 1000 in a certain direction or controls the operating characteristics of the hyperspectral image sensor 1000 (adjusting of a read-out timing, etc.) in order to compensate for a negative influence of the motion. The image stabilizer 1940 may sense the movement of the camera module 1880 or the electronic apparatus 1801 by using a gyro sensor (not shown) or an acceleration sensor (not shown) arranged inside or outside the camera module 1880. The image stabilizer 1940 may be implemented as an optical type.

The memory 1950 may store some or entire data of the image obtained through the hyperspectral image sensor 1000 for next image processing operation. For example, when a plurality of images are obtained at a high speed, obtained original data (Bayer-patterned data, high resolution data, etc.) is stored in the memory 1950, and a low resolution image is only displayed. Then, original data of a selected image (user selection, etc.) may be transferred to the image signal processor 1960. The memory 1950 may be integrated with the memory 1830 of the electronic apparatus 1801, or may include an additional memory that operates independently.

The image signal processor 1960 may perform image processing operations on the image obtained through the hyperspectral image sensor 1000 or the image data stored in the memory 1950. The image processing operations may include depth map generation, three-dimensional modeling, panorama generation, extraction of features, an image combination, and/or an image compensation (noise reduction, resolution adjustment, brightness adjustment, blurring, sharpening, softening, etc.) The image signal processor 1960 may perform control operations (exposure time control, read-out timing control, etc.) on the components (hyperspectral image sensor 1000, etc.) included in the camera module 1880. The image processed by the image signal processor 1960 may be stored again in the memory 1950 for additional process, or may be provided to an external component of the camera module 1880 (e.g., the memory 1830, the display device 1860, the electronic apparatus 1802, the electronic apparatus 1804, the server 1808, etc.) The image signal processor 1960 may be integrated with the processor 1820, or may be configured as an additional processor that is independently operated from the processor 1820. When the image signal processor 1960 is configured as an additional processor separately from the processor 1820, the image processed by the image signal processor 1960 may undergo through an additional image processing operation by the processor 1820 and then may be displayed on the display device 1860.

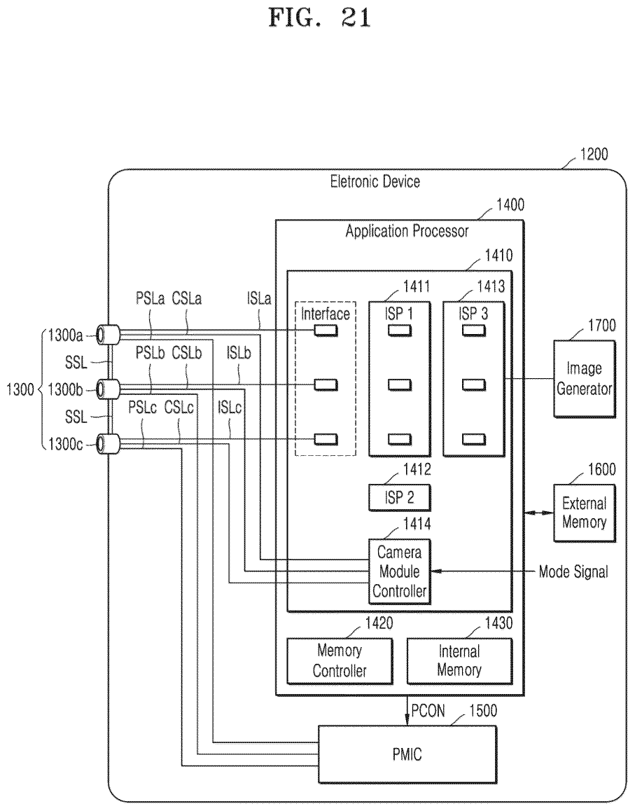

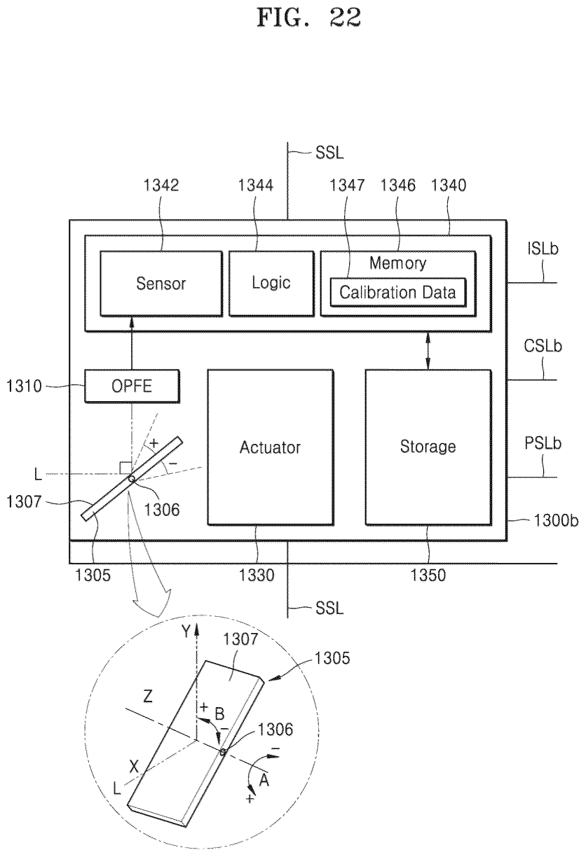

FIG. 21 is a block diagram of an electronic device 1200 including a multi-camera module, and FIG. 22 is a detailed block diagram of one camera module of the electronic device 1200 shown in FIG. 21.

Referring to FIG. 21, the electronic device 1200 may include a camera module group 1300, an application processor 1400, a power management integrated circuit (PMIC) 1500, an external memory 1600, and an image generator 1700.

The camera module group 1300 may include a plurality of the camera module 1300a, the camera module 1300b, and the camera module 1300c. The figures show one or more embodiments in which three camera modules, the camera module 1300a, the camera module 1300b, and the camera module 1300c are arranged, but the embodiments are not limited thereto. In some embodiments, the camera module group 1300 may be modified to include only two camera modules. In addition, in some embodiments, the camera module group 1300 may be modified to include n camera modules (n is a natural number of 4 or more).

Hereinafter, the detailed configuration of the camera module 1300b is described in more detail with reference to FIG. 22, but the following description may be equally applied to the camera module1300a and the camera module 1300c according to the embodiment.

Referring to FIG. 22, the camera module 1300b may include a prism 1305, an optical path folding element (hereinafter referred to as “OPFE”) 1310, an actuator 1330, an image sensing device 1340, and a storage 1350.

The prism 1305 may include a reflective surface 1307 of a light reflecting material to change a path of light L incident from the outside.

In some embodiments, the prism 1305 may change the path of light L incident in the first direction X to the second direction Y perpendicular to the first direction X. In addition, the prism 1305 may rotate the reflective surface 1307 of the light reflecting material in a direction A with respect to a central axis 1306, or rotate the central axis 1306 in a direction B to change the path of light L incident in the first direction X to the second direction Y perpendicular to the first direction X. At this time, the OPFE 1310 may also move in the third direction Z perpendicular to the first direction X and the second direction Y.

In some embodiments, as shown, the maximum rotation angle of the prism 1305 in the direction A may be 15 degrees or less in a direction plus (+) A and greater than 15 degrees in a direction minus (−) A, but the embodiments are not limited thereto.

In some embodiments, the prism 1305 may move about 20 degrees, between about 10 degrees and about 20 degrees, or between about 15 degrees and about 20 degrees in a direction plus (+) B or minus (−) B, where the moving angle may be the same in the direction plus (+) B or minus (−) B, or almost similar within a range of about 1 degree.

In some embodiments, the prism 1305 may move the reflective surface 1307 of the light reflecting material in the third direction (e.g., Z) parallel to a direction of extension of the central axis 1306.

The OPFE 1310 may include, for example, an optical lens including m groups (where m is a natural number). The m lenses may by moving in the second direction Y to change an optical zoom ratio of the camera module 1300b. For example, assuming that a basic optical zoom ratio of the camera module 1300b is Z, when moving the m optical lenses included in the OPFE 1310, the optical zoom ratio of the camera module 1300b may be change to 3Z or 5Z or 10Z or higher.

The actuator 1330 may move the OPFE 1310 or an optical lens to a specific position. For example, the actuator 1330 may adjust a position of the optical lens so that the image sensor 1342 is positioned at a focal length of the optical lens for accurate sensing.

The image sensing device 1340 may include an image sensor 1342, control logic 1344, and memory 1346. The image sensor 1342 may sense an image of a sensing object by using the light L provided through the optical lens. The control logic 1344 may control the overall operation of the camera module 1300b. For example, the control logic 1344 may control the operation of the camera module 1300b according to a control signal provided through a control signal line CSLb.

As an example, the image sensor 1342 may include the planar nano-optical microlens array described above. The image sensor 1342 may receive more signals separated by wavelengths for each pixel by using a nanostructure-based planar nano-optical microlens array. Due to this effect, the amount of light required to generate high-quality images at high resolution and low light may be secured.

The memory 1346 may store information necessary for the operation of the camera module 1300b, such as calibration data 1347. The calibration data 1347 may include information necessary to generate image data by using the light L provided from the outside through the camera module 1300b. The calibration data 1347 may include, for example, information about a degree of rotation, information about the focal length, and information about the optical axis described above. When the camera module 1300b is implemented as a multi-state camera of which focal length changes according to the position of the optical lens, the calibration data 1347 may include a focal length value of the optical lens for each position (or state) and information related to auto focusing.

The storage 1350 may store image data sensed through the image sensor 1342. The storage 1350 may be disposed outside the image sensing device 1340 and may be implemented in the form of stacked with a sensor chip constituting the image sensing device 1340. In some embodiments, the storage 1350 may be implemented as an Electrically Erasable Programmable Read-Only Memory (EEPROM), but the embodiments are not limited thereto.

Referring to FIGS. 21 and 22 together, in some embodiments, each of the camera module 1300a, the camera module 1300b, and the camera module 1300c may include an actuator 1330. Accordingly, each of the camera module 1300a, the camera module 1300b, and the camera module 1300c may include the same or different calibration data 1347 according to the operation of the actuator 1330 included therein.

In some embodiments, one camera module (e.g., 1300b) of the camera module 1300a, the camera module 1300b, and the camera module 1300c may be a folded lens type camera module including the prism 1305 and OPFE 1310 described above, and the remaining camera modules (e.g., the camera module 1300a and the camera module 1300b) may be vertical type camera modules that do not include the prism 1305 and OPFE 1310, but embodiments are not limited thereto.

In some embodiments, one camera module (e.g., 1300c) of the plurality of the camera module 1300a, the camera module 1300b, and the camera module 1300c may be a vertical type camera module that extracts depth information by using, for example, infrared ray (IR).

In some embodiments, at least two camera modules (e.g., the camera module 1300a and the camera module 1300b) among the camera module 1300a, the camera module 1300b, and the camera module 1300c may have different fields of view. In this case, for example, optical lenses of at least two camera modules (e.g., the camera module 1300a and the camera module 1300b) among the camera module1300a, the camera module 1300b, and the camera module 1300c may be different from each other, but are not limited thereto.

In addition, in some embodiments, the camera module1300a, the camera module 1300b, and the camera module 1300c may have different fields of view. In this case, the optical lenses respectively included in the camera module 1300a, the camera module 1300b, and the camera module 1300c may also be different from each other, but are not limited thereto.

In some embodiments, the camera module 1300a, the camera module 1300b, and the camera module 1300c may be disposed to be physically separated from each other. That is, the camera module 1300a, the camera module 1300b, and the camera module 1300c do not divide and use a sensing area of one image sensor 1342 but an independent sensor 1342 may be disposed inside each of the camera module 1300a, the camera module 1300b, and the camera module 1300c.

Referring again to FIG. 21, the application processor 1400 may include an image processing device 1410, a memory controller 1420, and an internal memory 1430. The application processor 1400 may be implemented separately from the camera module 1300a, the camera module 1300b, and the camera module 1300c. For example, the application processor 1400 and the camera module 1300a, the camera module 1300b, and the camera module 1300c may be implemented separately as separate semiconductor chips.

The image processing device 1410 may include first image signal processors (ISPs) 1411, second ISP 1412, and third ISP 1413, and a camera module controller 1414.

Image data respectively generated from the camera module 1300a, the camera module 1300b, and the camera module 1300c may be provided to the image processing device 1410 through separate ones of image signal line ISLa, image signal line ISLb, and image signal line ISLc. Such image data transmission may be performed by using, for example, a Camera Serial Interface (CSI) based on Mobile Industry Processor Interface (MIPI), but the embodiments are not limited thereto.

The image data transmitted to the image processing device 1410 may be stored in the external memory 1600 before being transmitted to the first ISPs 1411 and the second ISP 1412. Image data stored in the external memory 1600 may be provided to the first ISP1411 and/or the second ISP 1412. The first ISP 1411 may correct the received image data to generate a video. The second ISP 1412 may correct the received image data to generate a still image. For example, the first ISP 1411 and the second ISP 1412 may perform preprocessing operations such as color correction and gamma correction on the image data.

The first ISP 1411 may include sub processors. When the number of sub processors is equal to the number of the camera module 1300a, the camera module 1300b, and the camera module 1300c, each of the sub processors may process image data provided from one camera module. When the number of sub processors is less than the number of the camera module 1300a, the camera module 1300b, and the camera module 1300c, at least one of the sub processors may process image data provided from a plurality of camera modules by using a timing sharing process. The image data processed by the first ISP1411 and/or the second ISP 1412 may be stored in the external memory 1600 before being transferred to the image processor 1413. The image data stored in the external memory 1600 may be transmitted to the second ISP 1412. The second ISP 1412 may perform post-processing operations such as noise correction and sharpening correction on the image data.

The image data processed by the third ISP 1413 may be provided to the image generator 1700. The image generator 1700 may generate a final image by using the image data provided from the image processor 1413 according to image generating information or a mode signal.

Specifically, the image generator 1700 may merge at least part of the image data generated from the camera module 1300a, the camera module 1300b, and the camera module 1300cwith different fields of view according to the image generating information or the mode signal to generate an output image. In addition, the image generator 1700 may select one of the image data generated from the camera module 1300a, the camera module 1300b, and the camera module 1300cwith different fields of view according to the image generating information or the mode signal to generate an output image.

In some embodiments, the image generating information may include a zoom signal or zoom factor. In addition, in some embodiments, the mode signal may be a signal, for example, based on a mode selected by a user.

When the image generating information is a zoom signal (zoom factor) and the camera module 1300a, the camera module 1300b, and the camera module 1300c have different observation fields (fields of views), the image generator 1700 may perform different operations according to the type of the zoom signal. For example, when the zoom signal is a first signal, the image generator 1700 may merge the image data output from the camera module 1300a and the image data output from the camera module 1300c, and then generate an output image by using a merged image signal and the image data output from the camera module 1300b that is not used for merging. When the zoom signal is a second signal different from the first signal, the image generator 1700 may not merge the image data but may select one of the image data output from the camera module 1300a, the camera module 1300b, and the camera module 1300c and generate an output image. However, the embodiments are not limited thereto, and the method of processing image data may be modified and implemented as necessary.

The camera module controller 1414 may respectively provide control signals to the camera module 1300a, the camera module 1300b, and the camera module 1300c. The control signals generated from the camera module controller 1414 may be respectively provided to the corresponding ones of the camera module 1300a, the camera module 1300b, and the camera module 1300c1300c through separate ones of control signal line CSLa, control signal line CSLb, and control signal line CSLc.

In some embodiments, the control signals provided from the camera module controller 1414 to the camera module 1300a, the camera module 1300b, and the camera module 1300c may include mode information according to the mode signal. Based on the mode information, the camera module 1300a, the camera module 1300b, and the camera module 1300c may operate in a first operation mode and a second operation mode in relation to a sensing speed.

In the first operation mode, the camera module 1300a, the camera module 1300b, and the camera module 1300c may generate an image signal at a first speed (e.g., generate an image signal at a first frame rate) and encode the image signal to a second speed higher than the first speed (e.g., encode an image signal of a second frame rate higher than the first frame rate), and transmit the encoded image signal to the application processor 1400. At this time, the second speed may be 30 times or less than the first speed.

The application processor 1400 may store the received image signal, that is, the encoded image signal, in the memory 1430 provided inside or the storage 1600 outside the application processor 1400, and then read and decode the encoded image signal from the memory 1430 or the storage 1600, and display image data generated based on the decoded image signal. For example, the first ISP 1411 and the second ISP 1412 of the image processing device 1410 may perform decoding and may also perform image processing on the decoded image signal.

In the second operation mode, the camera module 1300a, the camera module 1300b, and the camera module 1300c may generate image signals at a third speed lower than the first speed (e.g., generate image signals at a third frame rate lower than the first frame rate) and transmit the image signals to the application processor 1400. The image signals provided to the application processor 1400 may be signals that are not encoded. The application processor 1400 may perform image processing on the received image signals or store the image signals in the memory 1430 or the storage 1600.

The PMIC 1500 may supply power, for example, a power supply voltage, to each of the plurality of camera modules 1300a, 1300b, and 1300c. For example, the PMIC 1500, under the control of the application processor 1400, may supply first power to the camera module 1300a through a power signal line PSLa, supply second power to the camera module 1300b through a power signal line PSLb, and supply third power to the camera module 1300c through a power signal line PSLc.

The PMIC 1500 may generate power corresponding to each of the camera module 1300a, the camera module 1300b, and the camera module 1300c in response to a power control signal PCON from the application processor 1400, and may also adjust a power level. The power control signal PCON may include a power adjustment signal for each operation mode of the plurality of the camera module 1300a, the camera module 1300b, and the camera module 1300c. For example, the operation mode may include a low power mode, and in this regard, the power control signal PCON may include information about a camera module operating in the low power mode and the set power level. Levels of the power provided to the camera module 1300a, the camera module 1300b, and the camera module 1300c may be the same as or different from each other. In addition, the level of power may dynamically change.

A planar nano-optical microlens array with a planar nanostructure may easily determine an optical curvature profile of the lens surface by using the planar nanostructure. Therefore, the planar nano-optical microlens with an optimal shape in accordance with a CRA of incident light incident on a hyperspectral image sensor may be easily designed and manufactured.

In addition, the planar nano-optical microlens array may change an angle of incidence of incident light incident at a large CRA at the edge of the hyperspectral image sensor to be nearly perpendicular. In particular, the planar nano-optical microlens array may include various types of microlenses in consideration of a change in the CRA according to various positions on the hyperspectral image sensor. Accordingly, the sensitivity of pixels positioned at the edge of the hyperspectral image sensor may be improved to be similar to the sensitivity of pixels positioned at the center of the hyperspectral image sensor.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A hyperspectral image sensor comprising:
a sensor substrate comprising a plurality of photosensitive cells configured to detect light;
a hyperspectral filter array on the sensor substrate and comprising a plurality of unit filters respectively corresponding to the plurality of photosensitive cells, the hyperspectral filter array being configured to separate at least four different wavelengths of the light;
a buffer layer on the hyperspectral filter array; and
a planar nano-optical microlens array on the buffer layer and having a nano-pattern structure configured to condense the light onto the plurality of photosensitive cells, the planar nano-optical microlens array comprising a plurality of planar nano-optical microlenses respectively corresponding to the plurality of unit filters,
wherein each of the plurality of planar nano-optical microlenses comprises first refractive index nanostructures comprising a first dielectric material with a first refractive index, and a second refractive index structure comprising a second dielectric material with a second refractive index that is lower than the first refractive index, and the first refractive index nanostructures are arranged such that the light transmitted through each of the plurality of planar nano-optical microlenses has a convex phase profile, and
wherein at a periphery of the planar nano-optical microlens array, a phase profile of the light transmitted through each of the plurality of planar nano-optical microlenses is asymmetrical with respect to a peak area of the phase profile of each of the plurality of planar nano-optical microlenses, and widths of the first refractive index nanostructures disposed in the peak area of the phase profile of each of the plurality of planar nano-optical microlenses among the plurality of first refractive index nanostructures are different from each other and are arranged differently according to center wavelengths of transmission bands of different ones of the plurality of unit filters of each of the plurality of planar nano-optical microlenses.

2. The hyperspectral image sensor of claim 1, wherein smaller ones of the widths of the first refractive index nanostructures disposed in the peak area of the phase profile of each of the plurality of planar nano-optical microlenses are arranged as overlapping larger ones of the center wavelengths of the transmission bands of the plurality of unit filters.

3. The hyperspectral image sensor of claim 1, wherein an effective refractive index of each of the plurality of planar nano-optical microlenses, which is determined by a ratio of each of first refractive index nanostructures to the second refractive index structure, is greatest in a refractive index peak area of each of the plurality of planar nano-optical microlenses and is decreased towards a periphery of the refractive index peak area,
wherein the peak area of the phase profile is at the refractive index peak area, and
wherein smaller ones, of the widths of a first refractive index nanostructure having a greatest width among the first refractive index nanostructures in each of the plurality of planar nano-optical microlenses, are arranged as overlapping larger ones of the center wavelengths of the transmission bands of the plurality of unit filters.

4. The hyperspectral image sensor of claim 1, wherein at a periphery of the planar nano-optical microlens array, the peak area of the phase profile of each of the plurality of planar nano-optical microlenses is arranged from off-center of the plurality of planar nano-optical microlenses and toward a center of the planar nano-optical microlens array.

5. The hyperspectral image sensor of claim 1, wherein, at a periphery of the planar nano-optical microlens array, a distance between the peak area of the phase profile and a center of the plurality of planar nano-optical microlenses is greater at one of the planar nano-optical microlenses further from the center of the planar nano-optic microlens array than is another one of the planar nano-optical microlenses.

6. The hyperspectral image sensor of claim 1, wherein at a center of the planar nano-optical microlens array, the peak area of the phase profile is positioned at a center of the plurality of planar nano-optical microlenses, and the phase profile of the light transmitted through each of the plurality of planar nano-optical microlenses is symmetrical with respect to the center of the plurality of planar nano-optical microlenses.

7. The hyperspectral image sensor of claim 1, wherein each of the plurality of unit filters comprises:
a first reflector;
a second reflector on an upper portion of the first reflector; and
a plurality of cavities between the first reflector and the second reflector, and having resonance wavelengths of different bands.

8. The hyperspectral image sensor of claim 7, wherein the plurality of cavities have the resonance wavelengths of different bands by having different thicknesses and different effective refractive indices than each other.

9. The hyperspectral image sensor of claim 8, wherein thicknesses of portions of the buffer layer on upper portions of each of the plurality of cavities are different than each other according to the thicknesses of the plurality of cavities.

10. The hyperspectral image sensor of claim 9, wherein a combined thickness of the plurality of cavities and the portions of the buffer layer is constant.

11. The hyperspectral image sensor of claim 7, wherein each of the plurality of cavities has a same thickness, and
wherein each of the plurality of cavities comprises a first dielectric and a second dielectric which comprise different refractive indices than each other.

12. The hyperspectral image sensor of claim 1, wherein each of the first refractive index nanostructures has a nano-post shape, and
wherein in each of the plurality of planar nano-optical microlenses, the second refractive index structure surrounds the first refractive index nanostructures.

13. The hyperspectral image sensor of claim 1, wherein each of the first refractive index nanostructures has a nano-post shape, and
wherein in each of the plurality of planar nano-optical microlenses, the first refractive index nanostructures are arranged in any one of a 3×3 arrangement, a 4×4 arrangement, and a 5×5 arrangement.

14. The hyperspectral image sensor of claim 1, wherein each of the plurality of planar nano-optical microlenses comprises a first layer and a second layer on the first layer.

15. The hyperspectral image sensor of claim 1, wherein each of the plurality of planar nano-optical microlenses comprises a first layer and a second layer on the first layer, and
wherein at a periphery of the planar nano-optical microlens array, a distribution of ones of the first refractive index nanostructures and the second refractive index structure at the first layer is different from a distribution of other ones of the first refractive index nanostructures and the second refractive index structure at the second layer.

16. The hyperspectral image sensor of claim 1, wherein a thickness of the buffer layer is 1 to 3 times a longest wavelength of the light as transmitted by the plurality of unit filters.

17. The hyperspectral image sensor of claim 1, further comprising an anti-reflection film on the planar nano-optical microlens array.

18. The hyperspectral image sensor of claim 1, further comprising a plurality of band blocking filters configured to transmit only a specific wavelength band of the light and to absorb or reflect other wavelength bands of the light between the planar nano-optical microlens array and the hyperspectral filter array.

19. An electronic apparatus comprising:
a hyperspectral image sensor configured to convert an optical image into an electrical signal; and
a processor configured to control an operation of the hyperspectral image sensor and store and output a signal generated by the hyperspectral image sensor, wherein the hyperspectral image sensor comprises:
a sensor substrate comprising a plurality of photosensitive cells configured to detect light;
a hyperspectral filter array on the sensor substrate and comprising a plurality of unit filters respectively corresponding to the plurality of photosensitive cells, the hyperspectral filter array being configured to separate at least four different wavelengths of the light;
a buffer layer on the hyperspectral filter array; and
a planar nano-optical microlens array on the buffer layer and having a nano-pattern structure configured to condense the light onto the plurality of photosensitive cells, the planar nano-optical microlens array comprising a plurality of planar nano-optical microlenses respectively corresponding to the plurality of unit filters,
wherein each of the plurality of planar nano-optical microlenses comprises first refractive index nanostructures comprising a first dielectric material with a first refractive index, and a second refractive index structure comprising a second dielectric material with a second refractive index that is lower than the first refractive index, and the first refractive index nanostructures are arranged such that the light, as transmitted through each of the plurality of planar nano-optical microlenses has a convex phase profile, and
wherein at a periphery of the planar nano-optical microlens array, a phase profile of the light transmitted through each of the plurality of planar nano-optical microlenses, is asymmetrical with respect to a peak area of the phase profile of each of the plurality of planar nano-optical microlenses, and widths of the first refractive index nanostructures disposed in the peak area of the phase profile of each of the plurality of planar nano-optical microlenses among the plurality of first refractive index nanostructures are different from each other and are arranged differently according to center wavelengths of a transmission bands of different ones of the plurality of unit filters each of the plurality of planar nano-optical microlenses.
